(19) United States
(12) Patent Application Publication
(10) Pub. No.: US 2025/0333554 A1
(43) Pub. Date: Oct. 30, 2025

(54) POLYMER, RESIST COMPOSITION COMPRISING THE SAME AND PATTERN FORMATION METHOD USING THE SAME

(71) Applicant: Samsung Electronics Co., Ltd., Suwon-si (KR)

(72) Inventors: Hoyoon PARK, Suwon-si (KR); Cheol KANG, Suwon-si (KR); Yoonhyun KWAK, Suwon-si (KR); Soyeon KIM, Suwon-si (KR); Hana KIM, Suwon-si (KR); Sungan DO, Suwon-si (KR); Yonghoon MOON, Suwon-si (KR); Dmitry ANDROSOV, Suwon-si (KR); Jaejun LEE, Suwon-si (KR); Minyoung HA, Suwon-si (KR)

(73) Assignee: Samsung Electronics Co., Ltd., Suwon-si (KR)

(21) Appl. No.: 18/899,154

(22) Filed: Sep. 27, 2024

(30) Foreign Application Priority Data
Apr. 24, 2024 (KR) 10-2024-0054985

(51) Int. Cl. C08F 220/58; C08F 212/14; C08F 220/28; G03F 7/039

(52) U.S. Cl. CPC C08F 220/58; C08F 212/24; C08F 220/282; G03F 7/039

(57) ABSTRACT

Provided are a polymer, a resist composition including the same, and a method of forming a pattern by using the same. The polymer may include at least 20 mol % of a first repeating unit represented by Formula 1 below and the polymer not include a repeating unit A including at least one selected from an aryl group substituted with a hydroxy group and a heteroaryl group substituted with a hydroxy group.

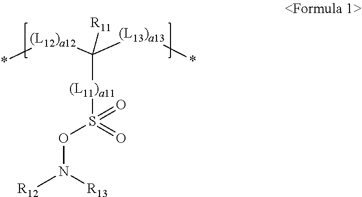

In Formula 1, L₁₁ to L₁₃, a11 to a13, X₁₁, and R₁₁ to R₁₃ are as described in the specification.

### CROSS-REFERENCE TO RELATED APPLICATION

This application is based on and claims priority under 35 U.S.C. § 119 to Korean Patent Application No. 10-2024-0054985, filed on Apr. 24, 2024, in the Korean Intellectual Property Office, the disclosure of which is incorporated by reference herein in its entirety.

### BACKGROUND

### 1. Field

The disclosure relates to a polymer, a resist composition including the same, and a method of forming a pattern by using the same.

### 2. Description of the Related Art

In semiconductor manufacturing, photoresists of which physical properties change in response to light are used to form fine patterns. Among these, chemically amplified photoresists have been widely used. A chemically amplified photoresist enables patterning because a base resin of the chemically amplified photoresist reacts with an acid produced by a reaction between light and a photoacid generator, resulting in a change in solubility of the base resin in a developer.

However, in the case of the chemically amplified photoresist, the produced acid may diffuse to an unexposed region, causing problems such as a decrease in uniformity of a pattern or an increase in surface roughness. In addition, as semiconductor processes become increasingly finer, it is not easy to control diffusion of an acid, and thus there may be a need to develop a new resist method.

Recently, attempts have been made to develop materials of which physical properties change with exposure to overcome the limitations of chemically amplified photoresists. However, the dose required for light exposure is still high.

Therefore, there may be a need to develop a material of which physical properties change at a low dose via a quick reaction.

### SUMMARY

Therefore, provided are a polymer, a resist composition including the same and a method of forming a pattern using the same, in which those physical properties, particularly solubility are changed by exposure light even at a low dose of light.

Additional aspects will be set forth in part in the description which follows and, in part, will be apparent from the description, or may be learned by practice of the presented embodiments of the disclosure.

According to an embodiment of the disclosure, a polymer may include at least 20 mol % of a first repeating unit represented by Formula 1 below and may not include a repeating unit A including at least one selected from an aryl group substituted with a hydroxy group and a heteroaryl group substituted with a hydroxy group.

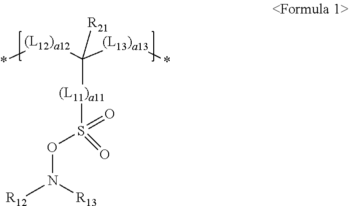

In Formula 1,

L₁₁ to L₁₃ each independently may be a single bond; O; S; C(═O); C(═O)O; OC(═O); C(═O)NH; NHC(═O); S(═O); S(═O)₂; S(═O)₂O; OS(═O)₂; or a linear, branched or cyclic C₁-C₃₀ divalent hydrocarbon group optionally including a heteroatom,

a11 to a13 each independently may be an integer from 1 to 4,

R₁₁ to R₁₃ each independently may be hydrogen; deuterium; a halogen; a cyano group; a hydroxy group; an amino group; a carboxylate group; a thiol group; a carbonyl moiety; an amide moiety; an ester moiety; a sulfonate moiety; a carbonate moiety; a carbamate moiety; a lactone moiety; a sultone moiety; a carboxylic anhydride moiety; or a linear, branched or cyclic C₁-C₃₀ monovalent hydrocarbon group optionally including a heteroatom,

R₁₂ and R₁₃ may optionally be bound to each other to form a ring, and

* is a binding site with an adjacent atom.

According to an embodiment of the disclosure, a resist composition may include the above-described polymer and an organic solvent.

According to an embodiment of the disclosure, a method of forming a pattern may include applying the above-described resist composition to form a resist film, exposing at least a portion of the resist film to high energy rays to provide an exposed resist film, and developing the exposed resist film using a developer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a method of forming a pattern, according to an embodiment,

FIGS. 2A to 2C are side cross-sectional views showing a method of forming a pattern, according to an embodiment,

FIGS. 3A to 3E are cross-sectional side views showing a method of forming a patterning structure, according to an embodiment, and

FIGS. 4A to 4E are side cross-sectional views showing a method of forming a semiconductor device, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As the disclosure allows for various changes and numerous embodiments, particular embodiments will be illustrated in the drawings and described in detail in the written description. However, this is not intended to limit the disclosure to particular modes of practice, and it is to be appreciated that all modifications, equivalents, and substitutes that do not depart from the spirit and technical scope of the disclosure are encompassed in the disclosure. In describing the disclosure, when it is determined that the specific description of the known related art unnecessarily obscures the gist of the disclosure, the detailed description thereof will be omitted.

Although the terms “first”, “second”, “third”, and the like may be used herein to describe various elements, these terms are only used to distinguish one element from another and the order, type, or the like of the elements are not limited thereby.

In this specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Unless explicitly described to the contrary, it is to be understood that the terms such as “including” and “having” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

The expression “Cr-Cy” used herein refers to the case where the number of carbon atoms constituting a substituent is in a range of x to y. For example, the expression “C₁-C₆” refers to the case where the number of carbon atoms constituting a substituent is in a range of 1 to 6, and the expression “C₆-C₂₀” refers to the case where the number of carbon atoms constituting a substituent is in a range of 6 to 20.

The term “monovalent hydrocarbon group” used herein refers to a monovalent residue derived from an organic compound including carbon and hydrogen or a derivative thereof, and specific examples thereof include a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cycloaliphatic hydrocarbon group (a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (an alkenyl group or an alkynyl group) (e.g., an allyl group); a monovalent unsaturated cycloaliphatic hydrocarbon group (a cycloalkenyl group) (e.g., 3-cyclohexenyl); an aryl group (e.g., a phenyl group, a 1-naphthyl group, and a 2-naphthyl group); an arylalkyl group (e.g., a benzyl group and a diphenylmethyl group); a heteroatom-including monovalent hydrocarbon group (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), or a combination thereof. Additionally, some of hydrogens in these groups may be substituted with a moiety including a heteroatom such as oxygen, sulfur, nitrogen, or halogen atoms, or some of carbons in these groups may be replaced by a moiety including a heteroatom such as oxygen, sulfur, or nitrogen, and thus these groups may include a hydroxy group, a cyano group, a carbonyl group, a carboxyl group, an ether bond, an amide bond, an ester bond, a sulfonate ester bond, a carbonate, a carbamate, a lactone ring, a sultone ring, a carboxylic anhydride moiety, or a haloalkyl moiety.

The term “divalent hydrocarbon group” as used herein is a divalent residue and refers to a system in which any one hydrogen atom of the monovalent hydrocarbon group is replaced by a binding site with an adjacent atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom, and the like.

The term “alkyl group” as used herein refers to a linear or branched saturated aliphatic monovalent hydrocarbon group, and examples thereof may include a methyl group, an ethyl group, a propyl group, an isobutyl group, a sec-butyl group, a tert-butyl group, a pentyl group, an iso-amyl group, and a hexyl group. The term “alkylene group” as used herein refers to a linear or branched saturated aliphatic divalent hydrocarbon group, and examples thereof may include a methylene group, an ethylene group, a propylene group, a butylene group, and an isobutylene group.

The term “halogenated alkyl group” as used herein refers to a group in which at least one substituent of an alkyl group is substituted with a halogen atom, and examples thereof include CF₃.

The term “alkoxy group” as used herein refers to a monovalent group represented by formula -OA₁₀₁, wherein A₁₀₁ is an alkyl group. Specific examples thereof include a methoxy group, an ethoxy group, an isopropyloxy group, and the like.

The term “alkylthio group” as used herein refers to a monovalent group represented by formula -SA₁₀₁, wherein A₁₀₁ is an alkyl group.

The term “halogenated alkoxy group” as used herein refers to a group in which one or more hydrogen atoms of an alkoxy group are substituted with a halogen atom, and specific examples thereof include —OCF₃ and the like.

The term “halogenated alkylthio group” as used herein refers to a group in which one or more hydrogen atoms of an alkylthio group are substituted with a halogen atom, and specific examples thereof include —SCF₃ and the like.

The term “cycloalkyl group” as used herein refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. The term “cycloalkylene group” as used herein refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “cycloalkoxy group” as used herein refers to a monovalent group represented by formula -OA₁₀₂, wherein A₁₀₂ is a cycloalkyl group. Specific examples thereof include a cyclopropoxy group, a cyclobutoxy group, and the like.

The term “cycloalkylthio group” as used herein refers to a monovalent group represented by formula -SA₁₀₂, where A₁₀₂ is a cycloalkyl group.

As used herein, the term “heterocycloalkyl group” refers to a cycloalkyl group in which some carbon atoms are substituted with a moiety including a heteroatom, such as oxygen, sulfur, or nitrogen, and the heterocycloalkyl group may specifically include an ether bond, an amide bond, an ester bond, a sulfonate ester bond, a carbonate, a carbamate, a lactone ring, a sultone ring, or a carboxylic anhydride moiety. The term “heterocycloalkylene group” as used herein refers to a group in which some carbon atoms of the cycloalkylene group are substituted with a moiety including a heteroatom such as oxygen, sulfur, or nitrogen.

The term “heterocycloalkoxy group” as used herein refers to a monovalent group represented by formula -OA₁₀₃, wherein A₁₀₃ is a heterocycloalkyl group.

The term “alkenyl group” as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including one or more carbon-carbon double bonds.

The term “alkenyloxy group” as used herein refers to a monovalent group represented by formula -OA₁₀₄, wherein A₁₀₄ is an alkenyl group.

The term “cycloalkenyl group” as used herein refers to a monovalent unsaturated hydrocarbon cyclic group including at least one carbon-carbon double bond. The term “cycloalkenylene group” as used herein refers to a divalent unsaturated hydrocarbon cyclic group including at least one carbon-carbon double bond.

The term “cycloalkenyloxy group” as used herein refers to a monovalent group represented by formula -OA₁₀₅, where A₁₀₅ is a cycloalkenyl group.

The term “heterocycloalkenyl group” as used herein refers to a cycloalkenylene group in which some carbon atoms are substituted with a moiety including a heteroatom, such as oxygen, sulfur, or nitrogen. The term “heterocycloalkenylene group” as used herein refers to a cycloalkenylene group in which some carbon atoms are substituted with a moiety including a heteroatom, such as oxygen, sulfur, or nitrogen.

The term “heterocycloalkenyloxy group” as used herein refers to a monovalent group represented by formula -OA₁₀₆, where A₁₀₆ is a heterocycloalkenyl group.

The term “alkynyl group” as used herein refers to a linear or branched monovalent unsaturated aliphatic hydrocarbon group including one or more carbon-carbon triple bonds.

The term “alkynyloxy group” as used herein refers to a monovalent group represented by formula -OA₁₀₇, where A₁₀₇ is an alkynyl group.

The term “aryl group” as used herein refers to a monovalent group including a carbocyclic aromatic system, and examples thereof include a phenyl group, a naphthyl group, an anthracenyl group, a phenanthrenyl group, a pyrenyl group, and a chrysenyl group.

The term “aryloxy group” as used herein refers to a monovalent group represented by formula -OA₁₀₈, where A₁₀₈ is an aryl group.

The term “heteroaryl group” as used herein refers to a monovalent group including a heterocyclic aromatic system, and examples thereof include a pyridinyl group, a pyrimidinyl group, and a pyrazinyl group. The term “heteroarylene group” as used herein refers to a divalent group including a heterocyclic aromatic system.

The term “heteroaryloxy group” as used herein refers to a monovalent group represented by formula -OA₁₀₉, where A₁₀₉ is a heteroaryl group.

As used herein, the term “substituent” includes deuterium, a halogen atom, a hydroxyl group, a cyano group, a nitro group, a carbonyl group, a carboxylate group, an amino group, an ether moiety, an ester moiety, a sulfonate ester moiety, a carbonate moiety, a carbamate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group; and

a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and C₁-C₂₀ heteroarylthio group, each substituted with deuterium, a halogen atom, a hydroxyl group, a cyano group, a nitro group, a carbonyl group, a carboxylate group, an amino group, an ether moiety, an ester moiety, a sulfonate ester moiety, a carbonate moiety, a carbamate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, or a combination thereof; and any combination thereof.

Hereinafter, embodiments will be described in detail with reference to the accompanying drawings, wherein like reference numerals denote substantially the same or corresponding components throughout the drawings, and a redundant description thereof will be omitted. In the drawings, thicknesses of various layers and regions are enlarged for clarity. Also, in the drawings, the thicknesses of some layers and regions are exaggerated for convenience of description. Meanwhile, embodiments set forth hereinafter are merely for illustrative purposes, and various changes may be made therein.

### [Polymer]

A polymer according to embodiments includes at least 20 mol % (e.g., greater than or equal to 20 mol % and less than or equal to 100 mol %) of a first repeating unit represented by Formula 1 below, and

the polymer may not include a repeating unit A including at least one selected from an aryl group substituted with a hydroxy group and a heteroaryl group substituted with a hydroxy group:

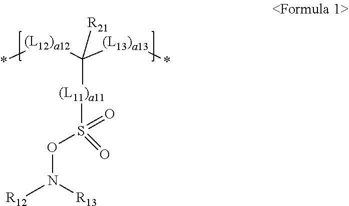

In Formula 1,

L₁₁ to L₁₃ are each independently a single bond; O; S; C(═O); C(═O)O; OC(═O); C(═O)NH; NHC(═O); S(═O); S(═O)₂; S(═O)₂O; OS(═O)₂; or a linear, branched or cyclic C₁-C₃₀ divalent hydrocarbon group optionally including a heteroatom,

a11 to a13 are each independently an integer from 1 to 4,

R₁₁ to R₁₃ are each independently hydrogen; deuterium; a halogen; a cyano group; a hydroxy group; an amino group; a carboxylate group; a thiol group; a carbonyl moiety; an amide moiety; an ester moiety; a sulfonate moiety; a carbonate moiety; a carbamate moiety; a lactone moiety; a sultone moiety; a carboxylic anhydride moiety; or a linear, branched or cyclic C₁-C₃₀ monovalent hydrocarbon group optionally including a heteroatom,

R₁₂ and R₁₃ may optionally be bound to each other to form a ring, and

* is a binding site with an adjacent atom.

For example, in Formula 1, L₁₁ to L₁₃ may be each independently a single bond; O; S; C(═O); C(═O)O; OC(═O); C(═O)NH; NHC(═O); S(═O); S(═O)₂; S(═O)₂O; OS(═O)₂; a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

As another example, in Formula 1, L₁₁ to L₁₃ may each independently be selected from a single bond; O; C(═O); C(═O)O; OC(═O); C(═O)NH; NHC(═O); and a C₁-C₂₀ alkylene group, a C₃-C₂₀ cycloalkylene group, a C₃-C₂₀ heterocycloalkylene group, a C₂-C₂₀ alkenylene group, a C₃-C₂₀ cycloalkenylene group, a C₃-C₂₀ heterocycloalkenylene group, a C₆-C₂₀ arylene group, and a C₁-C₂₀ heteroarylene group, which are unsubstituted or substituted with deuterium, a halogen, a cyano group, a hydroxy group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

As another example, in Formula 1, L₁₁ to L₁₃ are each independently a single bond; O; C(═O); C(═O)O; OC(═O); C(═O)NH; NHC(═O); and a C₁-C₂₀ alkylene group, a C₃-C₂₀ cycloalkylene group, a C₃-C₂₀ heterocycloalkylene group, a phenylene group and naphtylene group, which are unsubstituted or substituted with deuterium, a halogen, an ester moiety, a C₁-C₂₀ alkyl group, a C₁-C₂₀ halogenated alkyl group, a C₁-C₂₀ alkoxy group, phenyl group, naphthyl group, or any combination thereof.

In Formula 1, a11 to a13 each refer to numbers of repetition of L₁₁ to L₁₃, respectively.

For example, in Formula 1, a11 to a13 may each independently be an integer from 1 to 3.

As another example, in Formula 1, a11 to a13 may each independently be 1.

For example, in Formula 1, R₁₁ may be selected from hydrogen; deuterium; a halogen; a cyano group; a hydroxy group; an amino group; a carboxylate group; a thiol group; an amide moiety; an ester moiety; and a C₁-C₂₀ alkyl group, a C₃-C₂₀ cycloalkyl group, and a C₆-C₂₀ aryl group, which are unsubstituted or substituted with deuterium, a halogen, a cyano group, a hydroxy group, an amino group, a carboxylate group, a thiol group, an amide moiety, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, C₁-C₂₀ alkoxy group, C₃-C₂₀ cycloalkyl group, C₃-C₂₀ cycloalkoxy group, C₆-C₂₀ aryl group, or any combination thereof.

As another example, in Formula 1, R₁₁ may be selected from hydrogen; deuterium; a halogen; a cyano group; an amide moiety; an ester moiety; and a C₁-C₂₀ alkyl group and a C₆-C₂₀ aryl group, which are unsubstituted or substituted with deuterium, a halogen, a cyano group, or any combination thereof.

As another example, in Formula 1, R₁₁ may be H, D, F, C₁, C(═O)OCH₃, C(═O)N(CH₃)₂, CH₃, CHF₂, CHF₂, CF₃, CH₂CH₃, CHFCH₃, It may be CHFCH₂F, CHFCHF₂, CHFCF₃, CF₂CH₃, CF₂CH₂F, CF₂CHF₂, CF₂CF₃, CH₂Cl, CHC₁₂, CCl₃, CHClCH₃, CHClCH₂Cl, CHClCHCl₂, CHClCCl₃, CCl₂CH₃, CCl₂CH₂Cl, CCl₂CHCl₂, CCl₂CCl₃ or a phenyl group.

For example, in Formula 1, R₁₂ and R₁₃ may each independently be selected from hydrogen; deuterium; —C(═O)R₁₄; —C(R₁₄)═NR₁₅; —OR₁₄; —NR₁₄R₁₅; —S(═O)R₁₄; —S(═O)₂R₁₄; —S(═O)₂OR₁₄; and a C₁-C₂₀ alkyl group, a C₁-C₂₀ halogenated alkyl group, a C₃-C₂₀ cycloalkyl group, a C₆-C₂₀ aryl group and a C₁-C₂₀ heteroaryl group, which are unsubstituted or substituted with deuterium, a halogen, a hydroxyl group, a cyano group, a nitro group, a carboxylate group, an amino group, an ether moiety, a carbonyl moiety, an ester moiety, a sulfonate moiety, a carbonate moiety, a carbamate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group or any combination thereof, and

R₁₄ and R₁₅ may each independently be selected from hydrogen; deuterium; and a C₁-C₂₀ alkyl group, a C₁-C₂₀ halogenated alkyl group, a C₃-C₂₀ cycloalkyl group, a C₆-C₂₀ aryl group and a C₁-C₂₀ heteroaryl group, which are unsubstituted or substituted with deuterium, a halogen, a hydroxyl group, a cyano group, a nitro group, a carboxylate group, an amino group, an ether moiety, a carbonyl moiety, an ester moiety, a sulfonate moiety, a carbonate moiety, a carbamate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group or any combination thereof.

As another example, in Formula 1, R₁₂ and R₁₃ may each independently be selected from hydrogen; deuterium; —C(═O)R₁₄; —C(R₁₄)═NR₁₅; —S(═O)R₁₄; —S(═O)₂R₁₄; —S(═O)₂OR₁₄; and a C₁-C₂₀ alkyl group, a C₁-C₂₀ halogenated alkyl group, a C₃-C₂₀ cycloalkyl group, a C₆-C₂₀ aryl group, and a C₁-C₂₀ heteroaryl group, which are unsubstituted or substituted with deuterium, a halogen, a hydroxyl group, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof, and

R₁₄ and R₁₅ may each independently be selected from hydrogen; deuterium; and a C₁-C₂₀ alkyl group, a C₁-C₂₀ halogenated alkyl group, a C₃-C₂₀ cycloalkyl group, a C₆-C₂₀ aryl group, and a C₁-C₂₀ heteroaryl group, which are unsubstituted or substituted with deuterium, a halogen, a hydroxyl group, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

As another example, R₁₂ and R₁₃ may each independently be selected from —C(═O)R₁₄; —C(R₁₄)═NR₁₅; —S(═O)₂R₁₄; and a C₁-C₂₀ alkyl group, a C₆-C₂₀ aryl group, and a C₁-C₂₀ heteroaryl group, which are unsubstituted or substituted with deuterium, a halogen, a hydroxyl group, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof, and

R₁₄ and R₁₅ may each independently be selected from hydrogen; deuterium; and a C₁-C₂₀ alkyl group, a C₆-C₂₀ aryl group, and a C₁-C₂₀ heteroaryl group, which are unsubstituted or substituted with deuterium, a halogen, a hydroxyl group, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

In an embodiment, in Formula 1, *—N(R₁₂)R₁₃ may be represented by any one of the following Formulae 4-1 to 4-7:

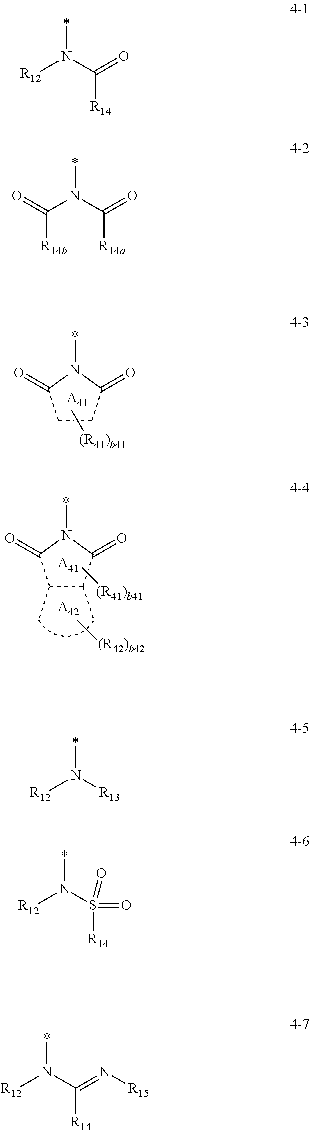

In Formulae 4-1 to 4-7,

R₁₂ and R₁₃ may each independently be selected from a C₁-C₂₀ alkyl group, a C₆-C₂₀ aryl group, and a C₁-C₂₀ heteroaryl group, which are unsubstituted or substituted with deuterium, a halogen, a hydroxyl group, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof,

R₁₄, R₁₅, R₁₄ₐ and R_{14b} may each independently be selected from hydrogen; deuterium; and a C₁-C₂₀ alkyl group, a C₆-C₂₀ aryl group, and a C₁-C₂₀ heteroaryl group, which are unsubstituted or substituted with deuterium, a halogen, a hydroxyl group, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof,

two adjacent groups among R₁₂ to R₁₅, R₁₄ₐ and R_{14b} may optionally bind to each other to form a ring,

A₄₁ and A₄₂ are each independently a C₁-C₃₀ cyclic alkyl group that may optionally include a heteroatom or a C₁-C₃₀ aryl group that may optionally include a heteroatom,

R₄₁ and R₄₂ are each independently hydrogen, deuterium, a halogen, a hydroxyl group, a cyano group, a nitro group, a C₁-C₂₀ alkyl group, a C₁-C₂₀ halogenated alkyl group, a C₃-C₂₀ cycloalkyl group, a C₆-C₂₀ aryl group, or a C₁-C₂₀ heteroaryl group,

b41 and b42 are each independently an integer from 1 to 10, and

* is a binding site with an adjacent atom.

In an embodiment, in Formula 1, *—N(R₁₂)R₁₃ may be represented by any one of the following Formulae 4-11 to 4-40:

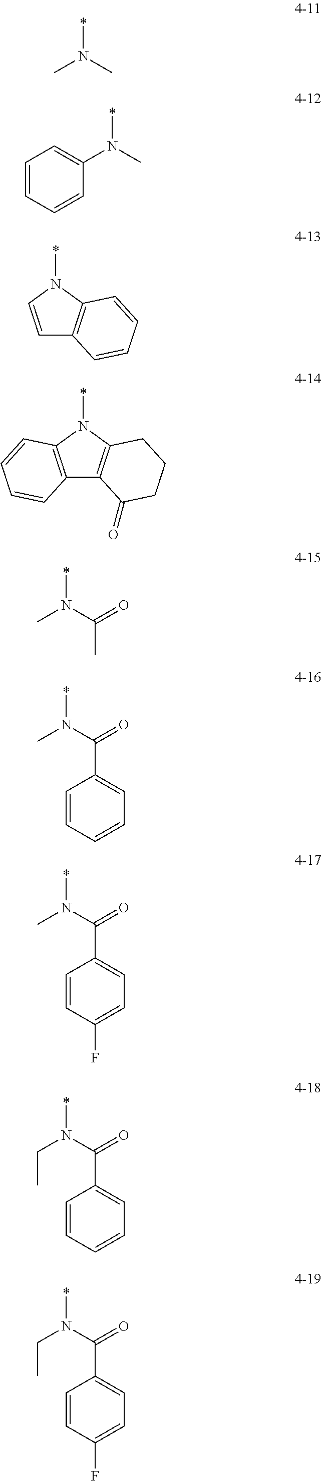

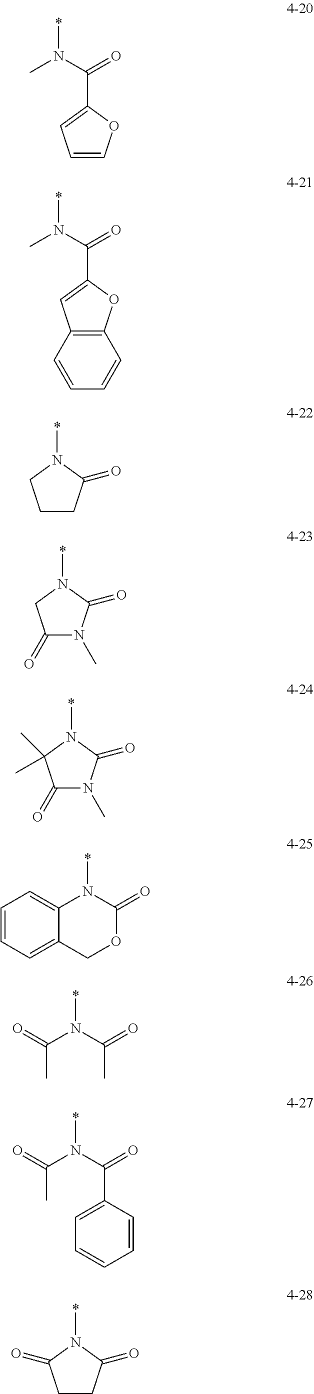

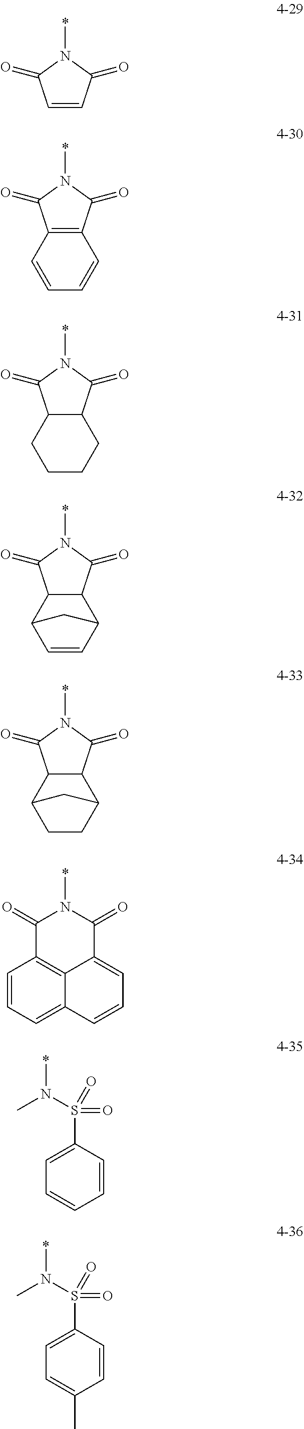

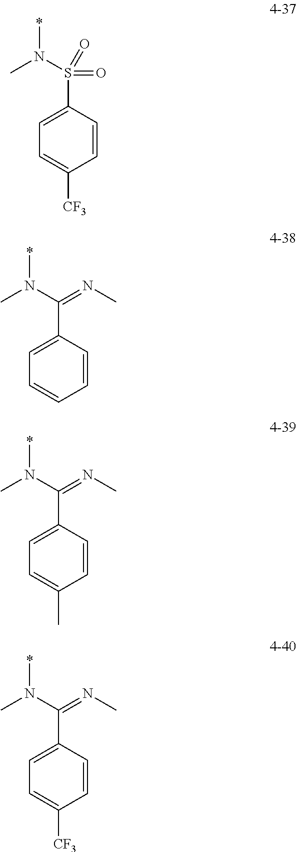

In Formulae 4-11 to 4-40,

* is a binding site with an adjacent atom.

In an embodiment, the first repeating unit may be selected from Group I below:

### <Group I>

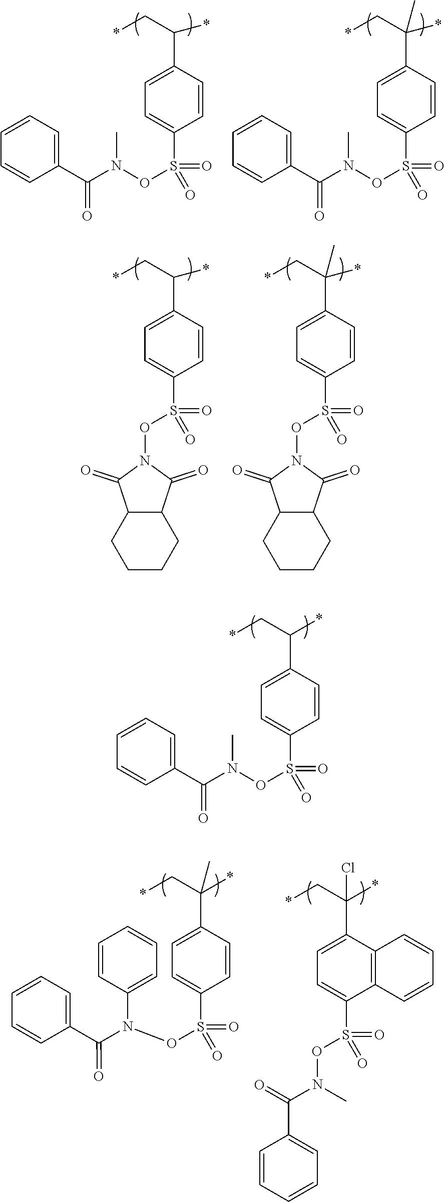

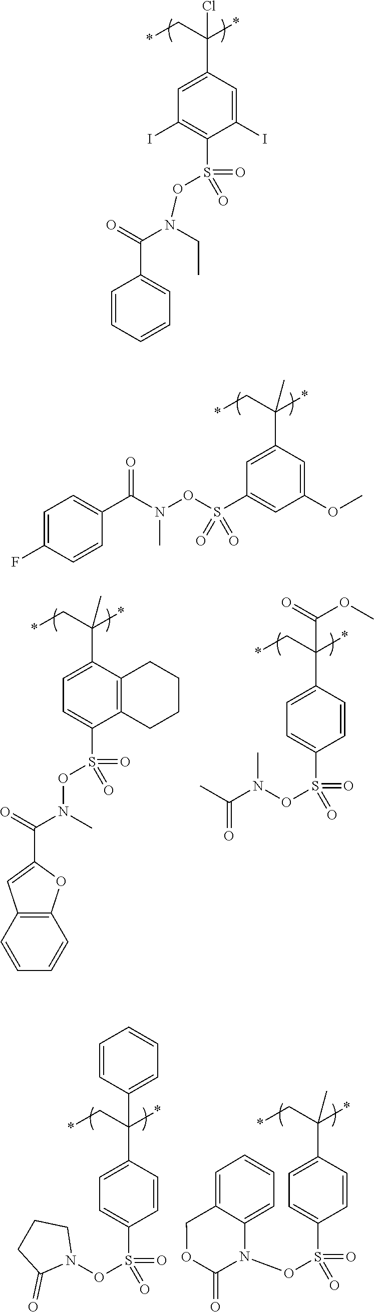

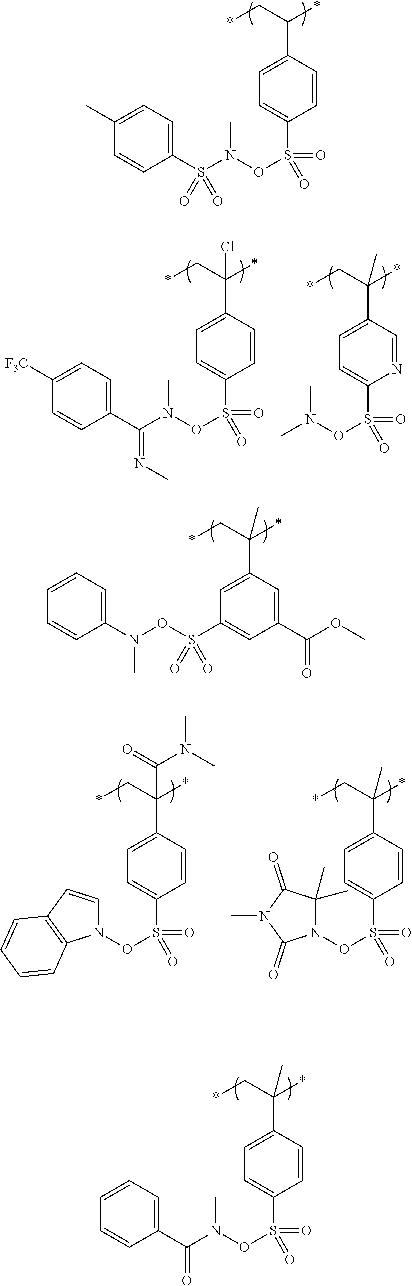

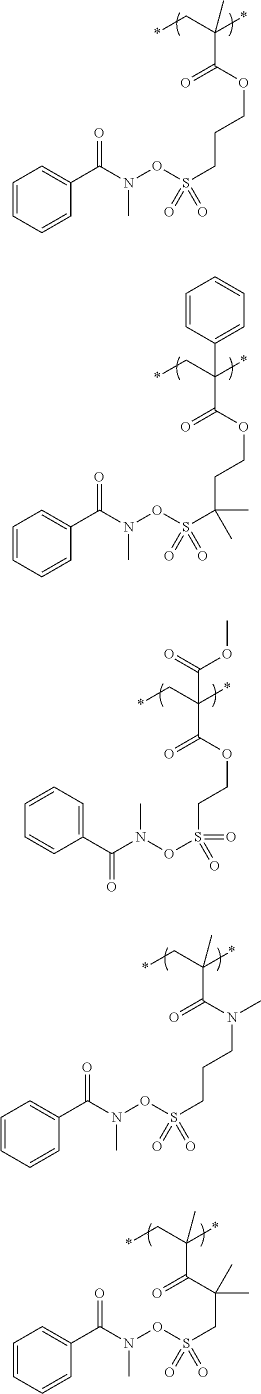

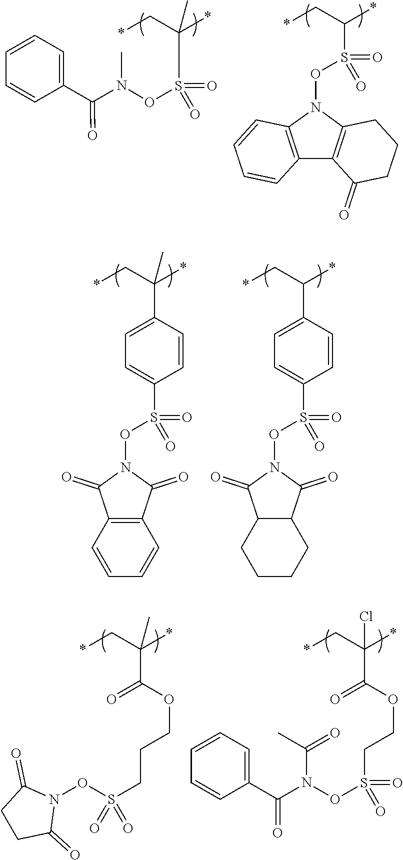

Since the polymer includes at least 20 mol % of a first repeating unit represented by Formula 1, a desired level of resist film thickness may be achieved. Specifically, the polymer may include at least 30 mol %, particularly at least 50 mol %, of the first repeating unit represented by Formula 1.

Here, the desired resist film thickness may be about 10 nm to about 300 nm in order to form a fine pattern with improved precision. More specifically, the resist film thickness may be about 20 nm to about 200 nm, about 20 nm to about 120 nm, about 20 nm to about 90 nm, especially about 30 nm to about 80 nm.

Since the polymer does not include a repeating unit A including at least one selected from a aryl group substituted with a hydroxy group and a heteroaryl group substituted with a hydroxy group, it may cause an appropriate change in solubility in the developer through exposure.

Specifically, the repeating unit A may be represented by the following Formula 10:

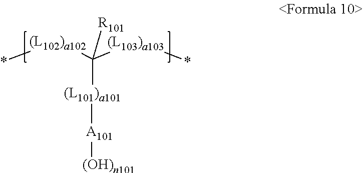

In Formula 10,

L₁₀₁ to L₁₀₃ are each independently a single bond; O; S; C(═O); C(═O)O; OC(═O); C(═O)NH; NHC(═O); S(═O); S(═O)₂; S(═O)₂O; OS(═O)₂; or a linear, branched or cyclic C₁-C₃₀ divalent hydrocarbon group optionally including a heteroatom,

a101 to a103 are each independently an integer from 1 to 4,

R₁₀₁ is hydrogen; deuterium; a halogen; a cyano group; a hydroxy group; an amino group; a carboxylate group; a thiol group; a carbonyl moiety; an ester moiety; a sulfonate moiety; a carbonate moiety; a carbamate moiety; a lactone moiety; a sultone moiety; a carboxylic anhydride moiety; or a linear, branched or cyclic C₁-C₃₀ monovalent hydrocarbon group optionally including a heteroatom,

A₁₀₁ is a substituted or unsubstituted C₆-C₃₀ aryl group or a substituted or unsubstituted C₁-C₃₀ heteroaryl group,

n101 is selected from integers from 1 to 5, and

* is a binding site with an adjacent atom.

Specifically, the repeating unit A may be represented by the following formula 10-1:

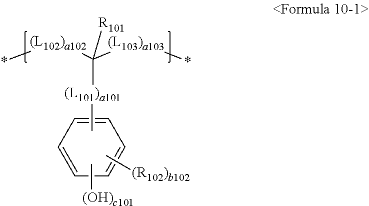

In Formula 10-1,

For descriptions of L₁₀₁ to L₁₀₃, a101 to a103, and R₁₀₁, refer to the above,

R₁₀₂ is hydrogen; deuterium; a halogen; a cyano group; a hydroxy group; an amino group; a carboxylate group; a thiol group; a carbonyl moiety; an ester moiety; a sulfonate moiety; a carbonate moiety; a carbamate moiety; a lactone moiety; a sultone moiety; a carboxylic anhydride moiety; or a linear, branched or cyclic C₁-C₃₀ monovalent hydrocarbon group optionally including an heteroatom,

c101 is selected from integers from 1 to 5,

b102 is selected from integers from 0 to 4,

* is a binding site with an adjacent atom.

Additionally, the polymer may not include a repeating unit whose structure changes due to acid.

Here, the repeating unit whose structure changes due to acid refers to a repeating unit including an acid labile group.

The acid labile group refers to a group that is detached from the polymer by acid to create a polar group, and has the effect of making the polymer more easily soluble in a developer, such as an aqueous TMAH solution.

The acid dissociation constant (pKa) of the acid labile group may be 13 or less, specifically about 3 to about 13, and more specifically about 5 to about 10 (calculated value).

For example, the acid labile group may refer to a group having a tertiary bicyclic alkyl carbon, a group including a tertiary alicyclic carbon, or an acetal.

More specifically, the acid labile group may mean an ester group having a tertiary bicyclic alkyl carbon, an ester group including a tertiary alicyclic carbon, a carbonate group having a tertiary bicyclic alkyl carbon, and a carbonate group including a tertiary alicyclic carbon, a carbamate group having a tertiary bicyclic alkyl carbon, a carbamate group including a tertiary alicyclic carbon, or an acetal and the like, for example, may be represented by any of the following Formulae 6-1 to 6-11:

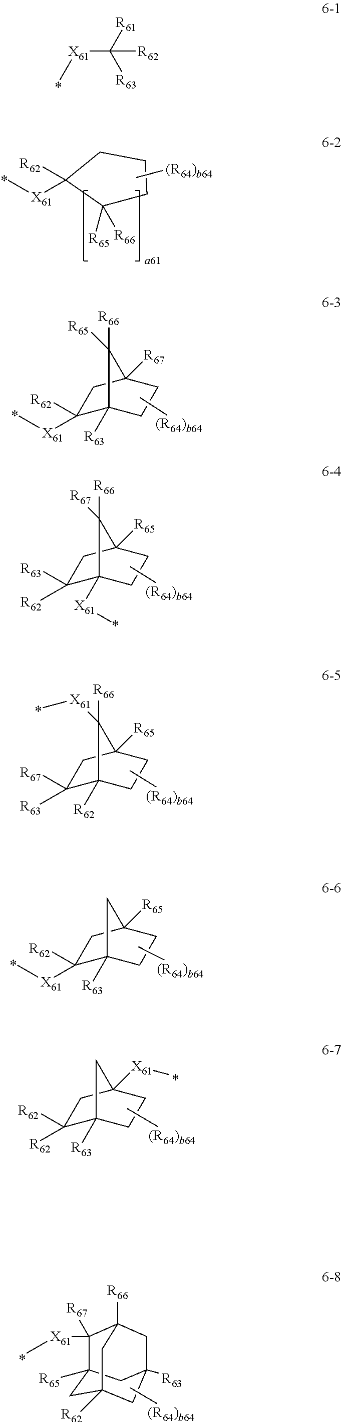

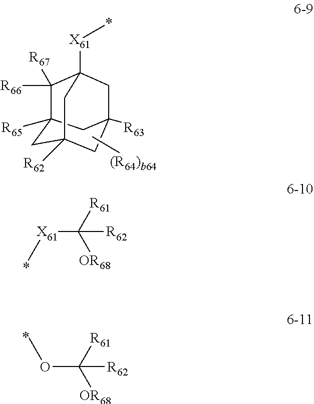

In Formulae 6-1 to 6-11,

X₆₁ is an ester moiety, a sulfonate moiety, a carbonate moiety, or a carbamate moiety;

a61 is selected from integers from 0 to 6;

R₆₁ and R₆₈ are each independently a linear, branched or cyclic C₁-C₂₀ monovalent hydrocarbon group optionally including a heteroatom,

R₆₂ to R₆₇ are each independently hydrogen; deuterium; a halogen; a cyano group; a hydroxy group; an amino group; a carboxylate group; a thiol group; an ester moiety; a sulfonate ester moiety; a carbonate moiety; a carbamate moiety; a lactone moiety; a sultone moiety; a carboxylic anhydride moiety; or a linear, branched or cyclic C₁-C₃₀ monovalent hydrocarbon group which may optionally include a heteroatom,

two adjacent groups among R₆₁ to R₆₈ may optionally bind to each other to form a ring,

b64 is selected from integers from 1 to 10, and

* is a binding site with an adjacent atom.

In an embodiment, the polymer may further include a second repeating unit represented by the following Formula 2:

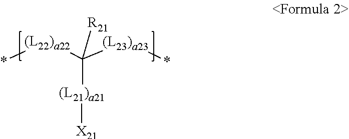

In Formula 2,

L₂₁ to L₂₃ are each independently a single bond; O; S; C(═O); C(═O)O; OC(═O); C(═O)NH; NHC(═O); S(═O)₂O; OS(═O)₂; or a linear, branched or cyclic C₁-C₃₀ divalent hydrocarbon group optionally including a heteroatom,

a21 to a23 are each independently an integer from 1 to 4,

R₂₁ is hydrogen; deuterium; a halogen; a cyano group; a hydroxy group; an amino group; a carboxylate group; a thiol group; a carbonyl moiety; an ester moiety; a sulfonate moiety; a carbonate moiety; a carbamate moiety; a lactone moiety; a sultone moiety; a carboxylic anhydride moiety; or a linear, branched or cyclic C₁-C₃₀ monovalent hydrocarbon group optionally including a heteroatom,

X₂₁ is a non-acid labile group, and

* is a binding site with an adjacent atom.

Specifically, in Formula 2, L₂₁ to L₂₃ each independently refer to the description of L₁₁.

Specifically, in Formula 2, a21 to a23 each independently refer to the description of a11.

Specifically, in Formula 2, R₂₁ refers to the description of R₁₁.

Specifically, in Formula 2, X₂₁ may not be an aryl group substituted with a hydroxy group or a heteroaryl group substituted with a hydroxy group.

More specifically, in Formula 2, X₂₁ may be hydrogen; a halogen; a cyano group; a hydroxy group; a carboxylate group; a thiol group; an amino group; or a linear, branched or cyclic C₁-C₃₀ monovalent hydrocarbon group optionally including one or more polar moieties selected from a halogen, a cyano group, a hydroxy group, a carboxylate group, a thiol group, O, C═O, C(═O)O, OC(═O), S(═O)O, OS(═O), a lactone moiety, a sultone moiety and a carboxylic anhydride moiety.

In an embodiment, in Formula 2, X₂₁ may be selected from hydrogen, a hydroxy group, a C₁-C₁₀ alkyl group, and groups represented by the following Formulae 5-1 to 5-15:

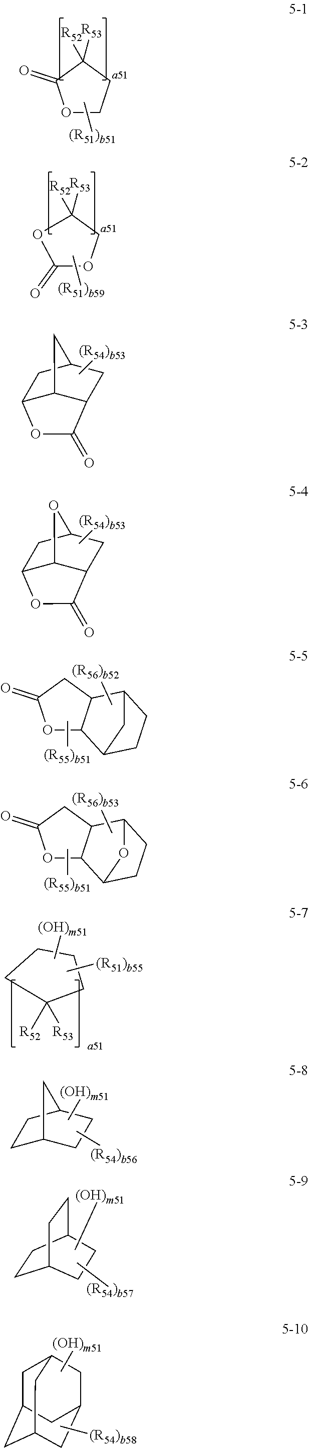

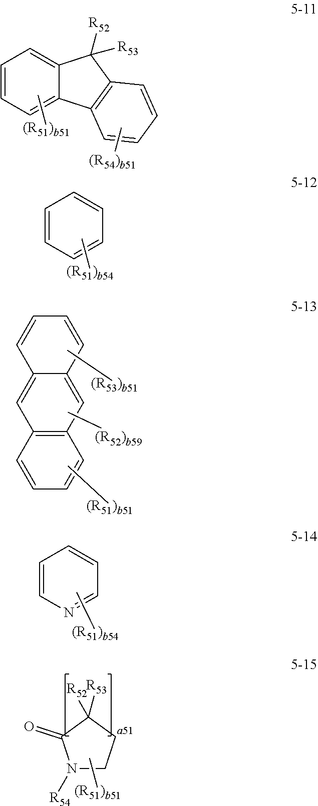

In Formulae 5-1 to 5-15,

a51 is 1 or 2;

R₅₁ to R₅₆ are each independently a binding site with an adjacent atom; hydrogen; deuterium; a halogen; a cyano group; a hydroxy group; an amino group; a carboxylate group; a thiol group; a carbonyl moiety; an ester moiety; a sulfonate moiety; a carbonate moiety; a carbamate moiety; a lactone moiety; a sultone moiety; a carboxylic anhydride moiety; or a linear, branched or cyclic C₁-C₃₀ monovalent hydrocarbon group optionally including a heteroatom,

One of R₅₁ to R₅₃, one of R₅₄ and one of R₅₅ and R₅₆ is a binding site with an adjacent atom,

b51 is selected from integers from 1 to 4,

b52 is selected from integers from 1 to 10,

b53 is selected from integers from 1 to 8,

b54 is selected from integers from 1 to 5,

b55 is selected from integers from 1 to 7,

b56 is selected from integers from 1 to 11,

b57 is selected from integers from 1 to 13,

b58 is selected from integers from 1 to 15,

b59 is selected from integers from 1 to 2, and

m51 is selected from integers from 1 to 4.

In particular, in Formula 2, X₂₁ may be selected from a hydroxy group and Formulae 5-1, 5-3, and 5-10.

In an embodiment, the second repeating unit may be represented by any one of the following Formulae 2-1 to 2-3:

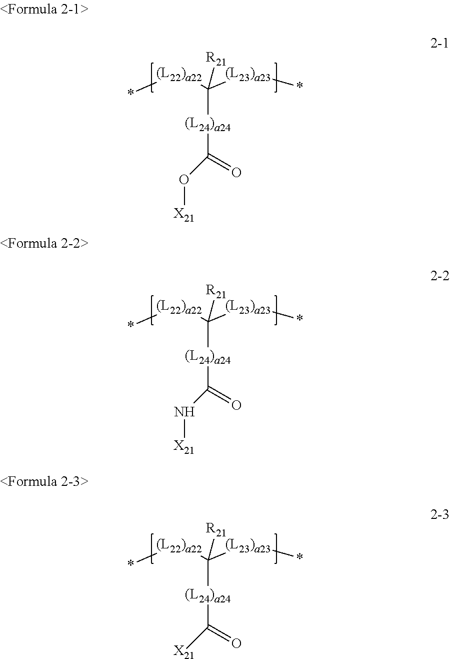

In Formulae 2-1 to 2-3,

For L₂₂ to L₂₃, a22 to a23, R₂₁ and X₂₁, refer to the description in Formula 2,

L₂₄ is a single bond; O; S; C(═O); C(═O)O; OC(═O); C(═O)NH; NHC(═O); S(═O)₂O; OS(═O)₂; or a linear, branched or cyclic C₁-C₃₀ divalent hydrocarbon group optionally including a heteroatom,

a24 is an integer from 1 to 3, and

* is a binding site with an adjacent atom.

In particular, in Formula 2-1, in Formula 2, X₂₁ may be selected from hydrogen, a hydroxy group, a C₁-C₁₀ alkyl group, and Formulae 5-1, 5-3, and 5-10 to 5-15.

In an embodiment, the second repeating unit may be a structure (e.g., polymer structure) represented by any one selected from Group II below:

### <Group II>

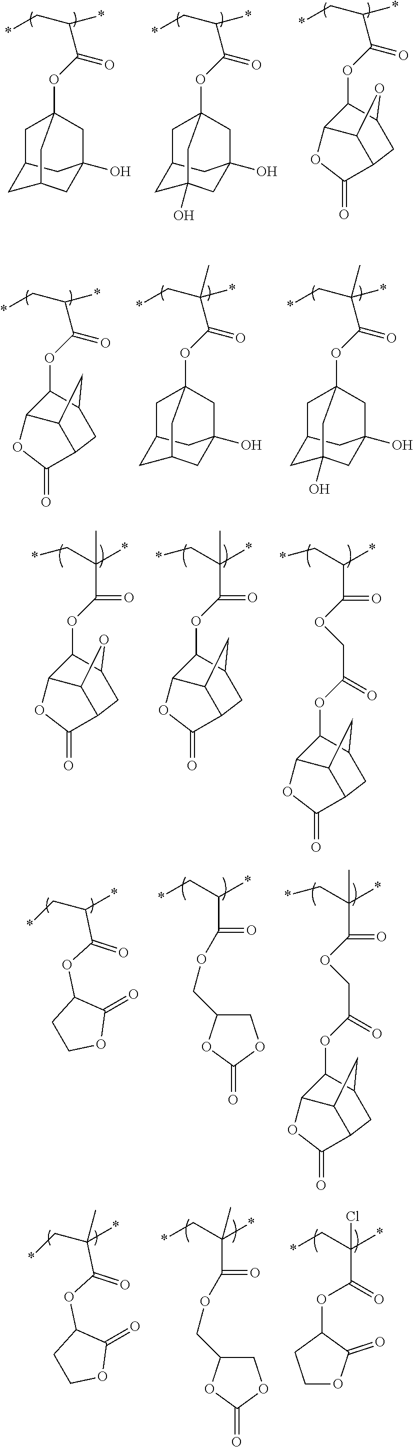

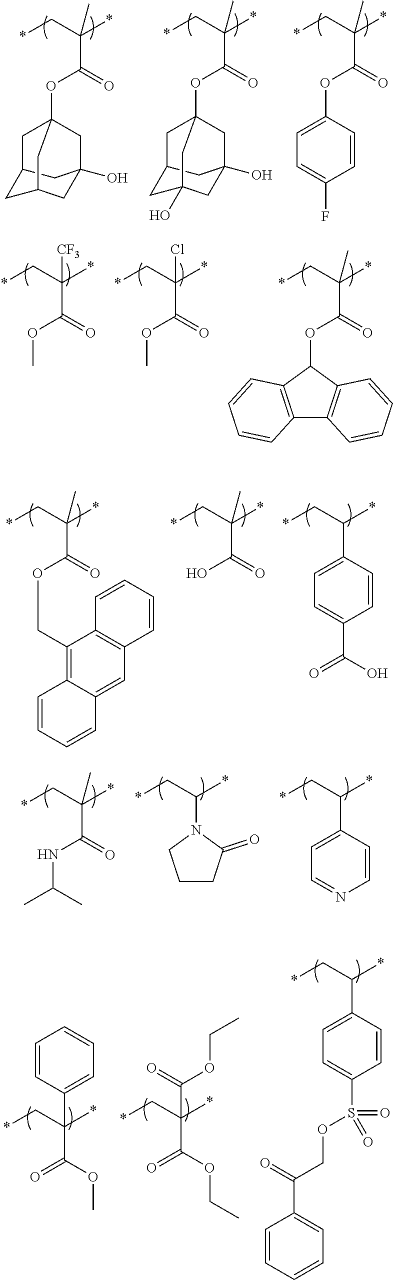

In an embodiment, the polymer may consist of the first repeating unit.

In an embodiment, the polymer may include about 1 to about 99 mol % of the first repeating unit and about 1 to about 99 mol % of the second repeating unit. Specifically, the polymer may include about 1 to about 90 mol % of the first repeating unit and about 10 to about 99 mol % of the second repeating unit. More specifically, the polymer may include about 10 to about 80 mol % of the first repeating unit and about 20 to about 90 mol % of the second repeating unit. In particular, the polymer may include the first repeating unit to the second repeating unit at a molar ratio of about 5:1 to about 1:5.

In another embodiment, the polymer may consist of the first repeating unit and the second repeating unit.

The polymer may have a weight average molecular weight (Mw) of about 1,000 to about 500,000, specifically, about 3,000 to about 200,000, as measured by gel permeation chromatography using tetrahydrofuran solvent and polystyrene as standard materials.

The polydispersity index (PDI: Mw/Mn) of the polymer may be about 1.0 to about 3.0. If the above-mentioned range is satisfied, it is easy to control the dispersibility and/or compatibility of the polymer, the possibility of foreign substances remaining on the pattern is reduced, or deterioration of the pattern profile may be minimized. Accordingly, the resist composition may become more suitable for forming fine patterns.

The polymer itself may change its physical properties by high-energy rays, so it may be used in a non-chemically amplified resist composition.

Since the polymer has relatively high resistance to oxygen and/or moisture, and its physical properties may be changed only by high-energy rays, a resist composition with improved storage stability and the like may be provided.

Since the polymer induces a change in the physical properties of the polymer through a change in the structure of the side chain, a resist composition capable of patterning with improved resolution and improved line edge roughness (LER) and/or improved line width roughness (LWR) even in a small dose of high-energy rays may be provided, compared to systems that induce physical property changes by decomposing the polymer main chain.

In particular, unlike chemically amplified photoresists, which can cause problems such as decreased pattern uniformity or increased surface roughness as the formed acid spreads to non-exposed areas, as the solubility of the polymer does not change due to acid, the lower uniformity of the pattern and/or the creation of defects due to acid diffusion may be reduced.

The polymer may be prepared by any suitable method, for example, by dissolving unsaturated bond-containing monomer(s) in an organic solvent and then thermally polymerizing them in the presence of a radical initiator.

The structure (composition) of the polymer may be confirmed by performing FT-IR analysis, NMR analysis, X-ray fluorescence (XRF) analysis, mass spectrometry analysis, UV analysis, single crystal X-ray structure analysis, powder X-ray diffraction (PXRD) analysis, and liquid chromatography (LC) analysis, size exclusion chromatography (SEC) analysis, thermal analysis, and the like. Detailed confirmation methods are as described in the examples.

### [Resist Composition]

According to another aspect of the disclosure, a resist composition includes the above-described polymer and an organic solvent. The resist composition may have properties such as improved developability and/or improved resolution.

Exposure to high-energy rays changes solubility of the resist composition in a developer. The resist composition may be a positive resist composition in which exposed portions of the resist film are dissolved and removed to form a positive resist pattern, or may be a negative resist composition in which unexposed portions of the resist film are dissolved and removed to form a negative resist pattern. In addition, the resist composition according to an embodiment may be one for an alkaline developing process using an alkaline developer for developing while forming a resist pattern, or may be one for a solvent developing process using an organic solvent-containing developer (hereinafter, referred to as organic developer) for development.

Because the resist composition is a non-chemically amplified type, the composition may not substantially include a photoacid generator.

The resist composition may not substantially include a compound having a molecular weight of 1,000 or more other than the polymer because physical properties of the polymer are changed by light exposure.

The polymer may be used in an amount of about 0.1 to about 80 parts by weight based on 100 parts by weight of the resist composition. Specifically, the polymer may be used in an amount of about 0.5 to about 5 parts by weight based on 100 parts by weight of the resist composition. If the above-described range is satisfied, loss of performance, e.g., a decrease in sensitivity and/or formation of particles of foreign matter caused by insufficient solubility may be reduced.

Because the polymer is as described above, hereinafter, the organic solvent and optional components included if required will be described. In addition, the polymer used may be used alone in the resist composition or at least two thereof may be used in combination.

### <Organic Solvent>

The organic solvent included in the resist composition is not particularly limited, as long as the polymer and any component included therein, if required, may be dissolved or dispersed therein. The organic solvent may be used alone or any combination of two or more different organic solvents may also be used. Also, a mixed solvent of water and an organic solvent may be used.

In an embodiment, the organic solvent may include a polar aprotic organic solvent.

In another example, the organic solvent may be a mixture of a polar aprotic organic solvent and a polar protic organic solvent.

Examples of the organic solvent may include alcohol-based solvents, ether-based solvents, ketone-based solvents, amide-based solvents, ester-based solvents, sulfoxide-based solvents, and hydrocarbon-based solvents.

More specifically, examples of the alcohol-based solvents may include: a monoalcohol-based solvent such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxy butanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonylalcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; a polyalcohol-based solvent such as ethyleneglycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethyleneglycol, dipropyleneglycol, triethylene glycol, and tripropylene glycol; and a polyalcohol-containing ether-based solvent such as ethyleneglycol monomethylether, ethyleneglycol monoethylether, ethyleneglycol monopropylether, ethyleneglycol monobutylether, ethyleneglycol monohexylether, ethyleneglycol monophenylether, ethyleneglycol mono-2-ethylbutylether, diethyleneglycol monomethylether, diethyleneglycol monoethylether, diethyleneglycol monopropylether, diethyleneglycol monobutylether, diethyleneglycol monohexyl ether, diethylene glycol dimethylether, propylene glycol monomethylether, propylene glycol dimethylether, propylene glycol monoethylether, propylene glycol monopropylether, propylene glycol monobutylether, dipropyleneglycol monomethylether, dipropyleneglycol monoethylether, and dipropyleneglycol monopropylether.

Examples of the ether-based solvents may include: a dialkylether-based solvent such as diethylether, dipropylether, and dibutylether; a cyclic ether-based solvent such as tetrahydrofuran and tetrahydropyran; and an aromatic ring-containing ether-based solvent such as diphenylether and anisole.

Examples of the ketone-based solvents may include: a chain-shaped ketone-based solvent such as acetone, methylethylketone, methyl-n-propylketone, methyl-n-butylketone, methyl-n-pentylketone, diethylketone, methylisobutylketone, 2-heptanone, ethyl-n-butylketone, methyl-n-hexylketone, diisobutylketone, and trimethylnonanone; a cyclic ketone-based solvent such as cyclopentanone, cyclohexanone, cycloheptanone, cyclooctanone, and methylcyclohexanone; and 2,4-pentanedione, acetonylacetone, and acetphenone.

Examples of the amide-based solvents may include: a cyclic amide-based solvent such as N,N′-dimethylimidazolidinone and N-methyl-2-pyrrolidone; and a chain-shaped amide-based solvent such as N-methylformamide, N,N-dimethylformamide, N,N-diethylformamide, acetamide, N-methylacetamide, N,N-dimethylacetamide, and N-methylpropyoneamide.

Examples of the ester-based solvents include: an acetate ester-based solvent such as methyl acetate, ethyl acetate, n-propyl acetate, isopropyl acetate, n-butyl acetate, isobutyl acetate, sec-butyl acetate, T-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; a polyalcohol-containing ethercarboxylate-based solvent such as ethyleneglycol monomethylether acetate, ethyleneglycol monoethylether acetate, diethyleneglycol monomethylether acetate, diethyleneglycol monoethylether acetate, diethyleneglycol mono-n-butyl ether acetate, propylene glycol monomethylether acetate (PGMEA), propylene glycol monoethylether acetate, propylene glycol monopropylether acetate, propylene glycol monobutylether acetate, dipropylene glycol monomethylether acetate, and dipropylene glycol monoethylether acetate; a lactone-based solvent such as γ-butyrolactone and δ-valerolactone; a carbonate-based solvent such as dimethyl carbonate, diethyl carbonate, ethylene carbonate, and propylene carbonate; a lactate ester-based solvent such as methyl lactate, ethyl lactate, n-butyl lactate, and n-amyl lactate; and glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and diethyl phthalate.

Examples of the sulfoxide-based solvents may include dimethyl sulfoxide and diethyl sulfoxide.

Examples of the hydrocarbon-based solvents include: an aliphatic hydrocarbon-based solvent such as n-pentane, isopentane, n-hexane, isohexane, n-heptane, isoheptane, 2,2,4-trimethyl pentane, n-octane, isooctane, cyclohexane, and methylcyclohexane; and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, and n-amylnaphthalene.

Specifically, the organic solvent may be selected from the ether-based solvent, the ester-based solvent, the ketone-based solvent, and any combination thereof. More specifically, the organic solvent may be selected from tetrahydrofuran, tetrahydropyran, γ-butyrolactone, δ-valerolactone, methyl ethyl ketone, methyl-n-propyl ketone, methyl-n-butyl ketone, methyl-n-pentylketone, cyclopentanone, cyclohexanone, cycloheptanone, cyclooctanone, methylcyclohexanone, and any combination thereof.

The organic solvent may be included in an amount of about 200 parts by weight to about 100,000 parts by weight, specifically, about 400 parts by weight to about 10.000 parts by weight based on 100 parts by weight of the polymer.

### <Optional Components>

The resist composition may further include a dissolution enhancer, a dissolution inhibitor, a surfactant, a crosslinking agent, a leveling agent, a colorant, or any combination thereof, if necessary.

Specifically, the resist composition may further include a dissolution inhibitor to improve developability, and the like. Examples of the dissolution inhibitors may include a phenolphthalein derivative, a fluorescein derivative, or any combination thereof. Specific examples of the dissolution inhibitors include Formulae I-1 to I-3 below.

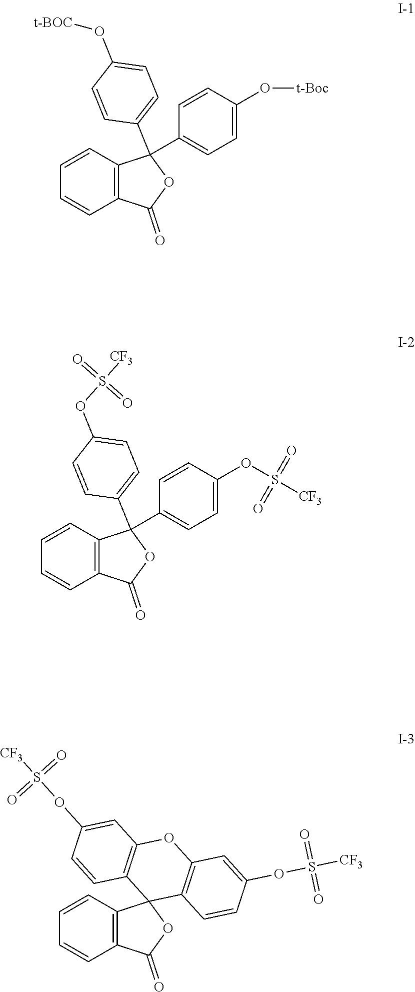

The resist composition may further include a surfactant to improve coatablity, developability, and the like. Examples of the surfactant may include a non-ionic surfactant such as polyoxyethylene lauryl ether, polyoxyethylene stearyl ether, polyoxyethyleneoleyl ether, polyoxyethylene n-octylphenyl ether, polyoxyethylene n-nonylphenyl ether, polyethyleneglycol dilaurate, and polyethyleneglycol distearate. Any commercially available product or a synthetic product may be used as the surfactant. Examples of the commercially available product may include KP341 (manufactured by Shin-Etsu Chemical Co., Ltd.), Polyflow No. 75 and Polyflow No. 95 (manufactured by Kyoeisha Chemical Co., Ltd.), Eftop EF301, Eftop EF303, and Eftop EF352 (manufactured by Mitsubishi Materials Electronic Chemicals Co., Ltd.), MEGAFACE® F171, MEGAFACE F173, R40, R41, and R43 (manufactured by DIC Corporation), Fluorad® FC430, Fluorad FC431 (manufactured by 3M Co., Ltd.), AsahiGuard AG710 (manufactured by AGC Co., Ltd.), and Surflon® S-382, Surflon SC-101, Surflon SC-102, Surflon SC-103, Surflon SC-104, Surflon SC-105, and Surflon SC-106 (manufactured by AGC Seimi Chemical Co., Ltd).

The surfactant may be included in an amount of about 0 parts by weight to about 20 parts by weight based on 100 parts by weight of the polymer. The surfactant may be used alone or any mixture of two or more different surfactants may also be used.

A method of preparing the resist composition is not particularly limited, and any method of mixing the polymer and optional components added as occasion demands in an organic solvent may also be used. Temperature or time in the mixing is not particularly limited. If necessary, filtration may be performed after the mixing.

### [Pattern Formation Method]

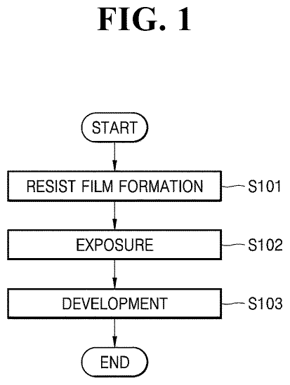

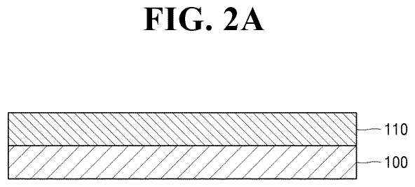

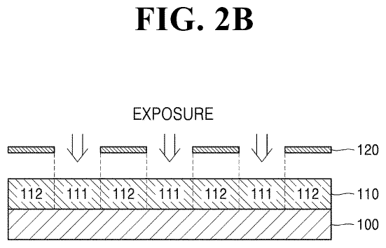

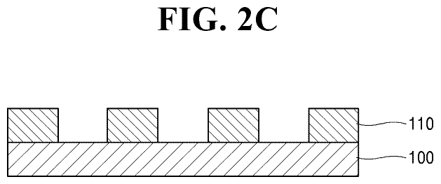

Hereinafter, a method of forming a pattern according to embodiments will be described in more detail with reference to FIG. 1 and FIGS. 2A to 2C. FIG. 1 is a flowchart illustrating a method of forming a pattern according to embodiments, and FIGS. 2A to 2C are side cross-sectional views illustrating a method of forming a pattern according to embodiments. Hereinafter, a method of forming a pattern using a positive resist composition will be described by way of an example, but the embodiment is not limited thereto.

Referring to FIG. 1, a method of forming a pattern includes applying a resist composition to form a resist film (S101), exposing at least a portion of the resist film to high-energy rays (S102), and developing the exposed resist film using a developer (S103). These operations may be omitted or may be performed in a different order, if necessary.

First, a substrate 100 is prepared. The substrate 100 may be a semiconductor substrate such as a silicon substrate and a germanium substrate, or may be formed of glass, quartz, ceramic, copper, or the like. In some embodiments, the substrate 100 may include Groups Ill to V compounds, such as GaP, GaAs, and GaSb.

A resist film 110 may be formed on the substrate 100 by applying the resist composition thereto to a desired thickness using a coating method. If necessary, the resist film 110 may be heated (pre-baked (PB) or post-annealing baked (PAB)) to remove the organic solvent remaining in the resist film 110.

As the coating method, spin coating, dipping, roller coating, or other common coating methods may be used. Among them, spin coating may particularly be used, and the resist film 110 having a desired thickness may be formed by adjusting viscosity, concentration, and/or spin speed of the resist composition. Specifically, the resist film 110 may have a thickness of about 10 nm to about 300 nm. More specifically, the resist film 110 may have a thickness of about 20 nm to about 200 nm.

A lower limit of a pre-baking temperature may be 60° C. or higher, specifically, 80° C. or higher. In addition, an upper limit of the pre-baking temperature may be 150° C. or less, specifically, 140° C. or lower. A lower limit of a pre-baking time may be 5 seconds or more, specifically, 10 seconds or more. An upper limit of the pre-baking time may be 600 seconds or less, specifically, 300 seconds or less.

Before applying the resist composition to the substrate 100, a film to be etched (not shown) may be formed on the substrate 100. The film to be etched may refer to a film onto which an image is transferred from a resist pattern to be converted into a pattern. In an embodiment, the film to be etched may be formed to include, for example, an insulating material such as a silicon oxide, a silicon nitride, and a silicon oxynitride. In some embodiments, the film to be etched may be formed to include a conductive material such as a metal, a metal nitride, a metal silicide, and a metal silicide nitride film. In some embodiments, the film to be etched may be formed to include a semiconductor material such as polysilicon.

In an embodiment, an anti-reflection film may further be formed on the substrate 100 to increase or maximize efficiency of the resist. The anti-reflection film may be an organic or inorganic anti-reflection film.

In an embodiment, a protective film may further be formed on the resist film 110 to reduce effects of alkaline impurities included during a process. In addition, in the case of performing immersion lithography, a protective film for immersion lithography may be formed on the resist film 110 to avoid direct contact between an immersion medium and the resist film 110.

Subsequently, at least a portion of the resist film 110 may be exposed to high-energy rays. For example, high-energy rays having passed through a mask 120 may reach at least one portion of the resist film 110. Therefore, the resist film 110 may have exposed regions 111 and unexposed regions 112.

Although not limited to a particular theory, as a side chain is decomposed in the exposed portion 111 by exposure to light, sulfonic acid that is acidic is produced at the side chain of the polymer, and thus solubility of the polymer in a developer, particularly, in an alkaline developer, may increase. Specifically, a reaction as shown in the schematic diagram below may occur.

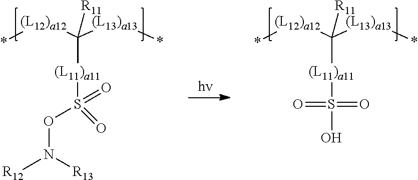

The exposure to light is performed by emitting high-energy rays through a mask having a particular pattern using a liquid such as water as a medium, if necessary. Examples of the high-energy rays may include electromagnetic waves such as ultraviolet rays, deep ultraviolet rays, extreme ultraviolet (EUV) rays (wavelength of 13.5 nm), X-rays, and γ-rays; and charged particle beams such as electron beams and a particle beams. Irradiation of these high-energy rays may be collectively referred to as “exposure”.

Various light sources may be used for the exposure, for example, a light source emitting laser beams in the UV range, such as a KrF excimer laser (wavelength of 248 nm), an ArF excimer laser (wavelength of 193 nm), and an F₂ excimer laser (wavelength of 157 nm), a light source emitting harmonic laser beams in the far ultraviolet or vacuum ultraviolet range by converting wavelengths of laser beams received from a solid laser light source (YAG or semiconductor laser), and a light source emitting electron beams or EUVs. During exposure, a mask corresponding to a desired pattern is commonly used, but, in the case of using electron beams as a light source for exposure, exposure may be directly performed without using a mask.

An integral dose of the high-energy rays may be 2000 mJ/cm² or less, specifically, 500 mJ/cm² or less, in the case of using extreme ultraviolet rays as the high-energy rays. In addition, in the case of using electron beams as the high-energy rays, the integral dose may be 5000 μC/cm² or less, specifically, 1000 μC/cm² or less.

Also, post exposure baking (PEB) may be performed after exposure. A lower limit of a PEB temperature may be 50° C. or higher, specifically, 80° C. or higher. An upper limit of the PEB temperature may be 180° C. or lower, specifically, 130° C. or lower. A lower limit of a PEB time may be 5 seconds or more, specifically, 10 seconds or more. An upper limit of the PEB time may be 600 seconds of less, specifically, 300 seconds or less.

Since the resist composition is substantially free of a photoacid generator, PEB may be omitted.

The exposed resist film 110 may be developed using a developer. The exposed regions 111 may be washed away by the developer, the unexposed regions 112 may remain without being washed by the developer. Or, on the contrary, the unexposed portion 112 may be washed away by the developer, or the exposed portion 111 may remain without being washed away by the developer.

As the developer, an alkaline developer, an organic solvent-containing developer (hereinafter, referred to as “organic developer”), and the like may be used. A developing method may be dipping, puddling, spraying, dynamic approach, or the like. A developing temperature may be, for example, from about 5° C. to about 60° C., and a developing time may be, for example, from about 5 seconds to about 300 seconds.

Examples of the alkaline developer may include an alkaline aqueous solution including at least one alkaline compound dissolved therein such as sodium hydroxide, potassium hydroxide, sodium carbonate, sodium silicate, sodium metasilicate, aqueous ammonia, ethylamine, n-propylamine, diethylamine, di-n-propyl amine, triethylamine, methyldiethylamine, ethyldimethylamine, triethanolamine, tetramethyl ammonium hydroxide (TMAH), pyrrole, piperidine, choline, 1,8-diazabicyclo [5.4.0]-7-undecene (DBU), and 1,5-diazabicyclo [4.3.0]-5-nonene (DBN). The alkaline developer may further include a surfactant.

A lower limit of an amount of the alkaline compound contained in the alkaline developer may be 0.1 mass % or more, specifically, 0.5 mass % or less, more specifically, 1 mass % or more. In addition, an upper limit of the amount of the alkaline compound contained in the alkaline developer may be 20 mass % or less, specifically, 10 mass % or less, more specifically, 5 mass % or less.

After development, the resist pattern may be washed with ultrapure water, and then, water remaining on the substrate and the pattern may be removed.

For example, the organic solvent contained in the organic developer may be the same as those described above in the <Organic Solvent> section of the [Resist Composition].

In the organic developer, a lower limit of the amount of the organic solvent may be 80 wt % or more, specifically, 90 wt % or more, more specifically, 95 wt % or more, particularly, 99 wt % or more.

The organic developer may include a surfactant. In addition, the organic developer may include a trace amount of moisture. In addition, development may be stopped during developing by replacing the organic developer with a different type of solvent.

The resist pattern may further be washed after the developing. Ultrapure water, a ringing solution, and the like may be used as a washing solution. The rinsing solution is not particularly limited as long as the resist pattern is not dissolved therein, and any solution including a common organic solvent may be used. For example, the rinsing solution may be an alcohol-based solvent or an ester-based solvent. After washing, the rinsing solution remaining on the substrate and the pattern may be removed. Also, in the case of using ultrapure water, water remaining on the substrate and the pattern may be removed.

In addition, the developer may be used alone or any combination of two or more different developers may also be used.

After the resist pattern is formed as described above, a pattered wiring substrate may be obtained by etching. Any etching methods well known in the art such as dry etching using plasma gas, and wet etching using an alkaline solution, a copper (II) chloride solution, or a ferric chloride solution may be used.

After forming the resist pattern, plating may be performed. Although a plating method is not particularly limited, for example, copper plating, solder plating, nickel plating, and gold plating may be used.

The resist pattern remaining after etching may be stripped off using an organic solvent. Examples of the organic solvent may be, but are not limited to, propylene glycol monomethylether acetate (PGMEA), propylene glycol monomethylether (PGME), and ethyl lactate (EL). Although a stripping is not particularly limited, for example, immersing and spraying may be used. In addition, a wiring substrate on which the resist pattern is formed may be a multi-layered wiring substrate or may have a small-diameter through hole.

In an embodiment, the wiring substrate may be formed by a method including forming a resist pattern, depositing a metal thereon in a vacuum, and melting the resist pattern using a solution, i.e., a lift-off method.

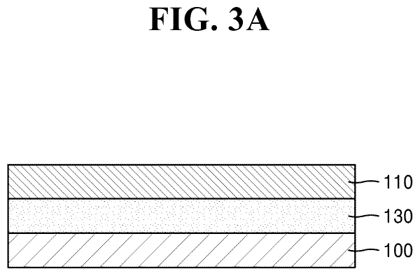

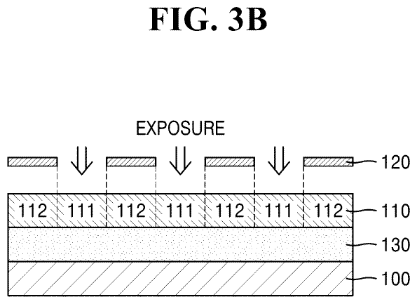

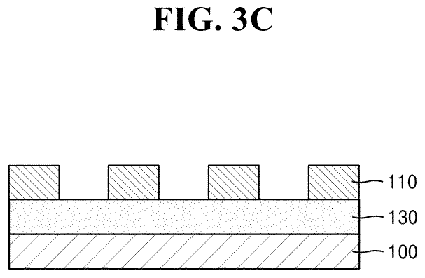

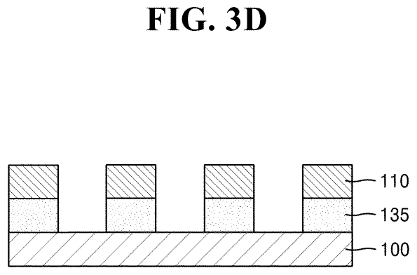

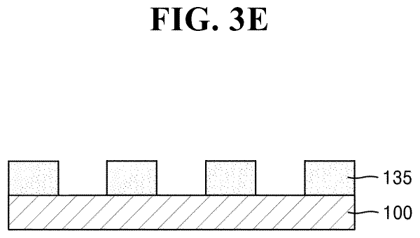

FIGS. 3A to 3E are cross-sectional side views showing a method of forming a patterning structure according to an embodiment of the disclosure.

As shown in FIG. 3A, a material layer 130 may be formed on the substrate 100 before forming the resist film 110 on the substrate 100. A resist film 110 may be formed on top of the material layer 130. The material layer 130 may include an insulating material (for example, silicon oxide, silicon nitride), a semiconductor material (for example, silicon), or a metal (for example, copper). In some embodiments, the material layer 130 may have a multi-layer structure. The material of the material layer 130 may be different from the material of the substrate 100.

As shown in FIG. 3B, the resist film 110 goes through a pre-exposure bake process and may be exposed to high-energy rays through a mask 120, and then the resist film 110 may include exposed regions 111 and unexposed regions 112.

As shown in FIG. 3C, the exposed resist film 110 may be developed using a developer. The exposed regions 111 may be washed away by the developer, and the unexposed regions 112 may remain without being washed away by the developer.

As shown in FIG. 3D, the exposed portion of the material layer 130 may be etched using the resist pattern 110 as a mask to form a material pattern 135 on the substrate 100.

As shown in FIG. 3E, the resist pattern 110 may be removed.

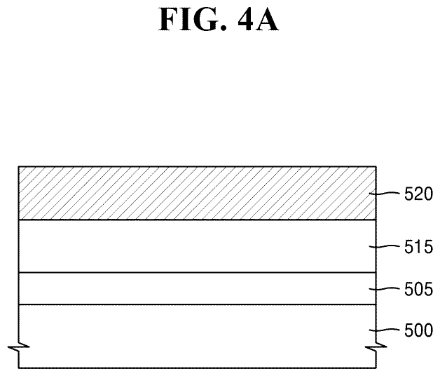

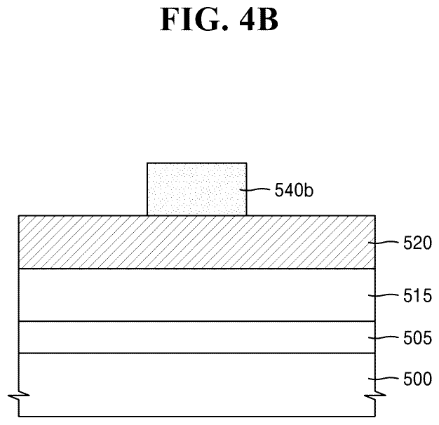

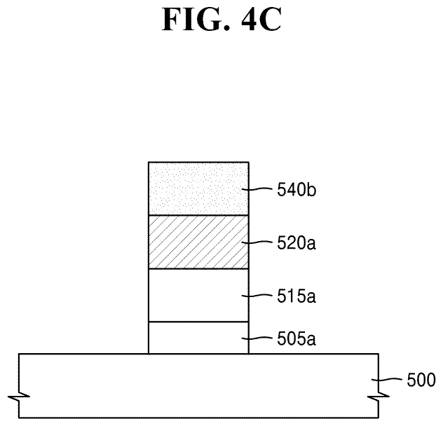

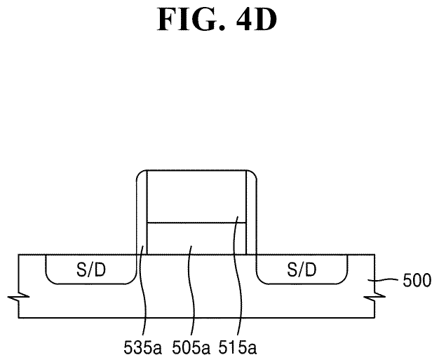

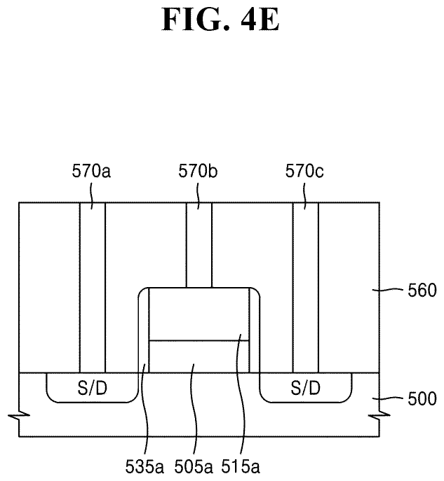

FIGS. 4A to 4E are side cross-sectional views showing a method of forming a semiconductor device according to an embodiment.

As shown in FIG. 4A, a gate dielectric 505 (for example, silicon oxide) may be formed on a substrate 500. The substrate 500 may be a semiconductor substrate such as a silicon substrate. The gate layer 515 (for example, doped polysilicon) may be formed on gate dielectric 505. A hardmask layer 520 may be formed on the gate layer 515.

As shown in FIG. 4B, a resist pattern 540b may be formed on a hard mask layer 520. The resist pattern 540b may be formed using a resist composition according to an embodiment of the disclosure. The resist composition may include an organic solvent.

As shown in FIG. 4C, the gate layer 515 and the gate dielectric 505 may be etched to form a hard mask pattern 520a, a gate electrode pattern 515a, and a gate dielectric pattern 505a.

As shown in FIG. 4D, the hard mask pattern 520a optionally may be removed and a spacer layer may be formed on the gate electrode pattern 515a and the gate dielectric pattern 505a. The spacer layer may be formed using a deposition process (for example, CVD). The spacer layer may be etched to form a spacer 535a (for example, silicon nitride) on the sidewalls of the gate electrode pattern 515a and the gate dielectric pattern 505a. After forming the spacer 535a, ions may be implanted into the substrate 500 to form source/drain impurity regions (S/D).

As shown in FIG. 4E, an interlayer insulating film 560 (for example, oxide) may be formed on the substrate 500 to cover the gate electrode pattern 515a, the gate dielectric pattern 505a, and the spacer 535a. Thereafter, electrical contact regions 570a, 570b, and 570c connected to the gate electrode 515a and the S/D region may be formed in the interlayer insulating film 560. The electrical contact regions 570a, 570b, and 570c may be formed of a conductive material (for example, metal). Although not shown, a barrier layer may be formed between the sidewall of the interlayer insulating film 560 and the electrical contact regions 570a, 570b, and 570c.

FIGS. 4A to 4E show examples of forming transistors, but the disclosure is not limited thereto.

The resist composition according to an embodiment may be used in a patterning process to form other types of semiconductor devices.

Although not illustrated in FIGS. 4D and 4E, in some embodiments, the hard mask pattern 520a may not be removed before the spacer 535a is formed. For example, if the hard mask pattern 520a is not removed, then the hard mask pattern 520a may remain on the gate electrode 515a in FIGS. 4D and 4E, the spacer 535a may cover a sidewall of the hard mask pattern 520a in FIGS. 4D and 4E, and the electrical contact 570b may extend through an opening in the hard mask pattern 520a to directly contact an upper surface of the gate electrode 515a.

The disclosure will be described in more detail using the following examples and comparative examples, but the technical scope of the disclosure is not limited to the following examples.

### EXAMPLE

### Synthesis Example 1: Synthesis of P1

### (1) Synthesis of Monomer A1

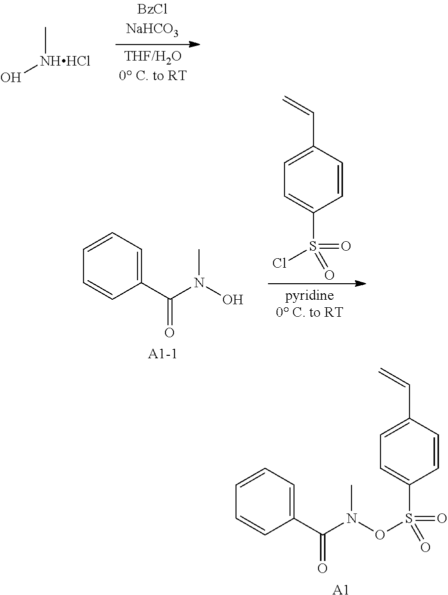

### 1) Synthesis of Compound A1-1

N-methylhydroxylamine hydrochloride (4.816 g, 57.66 mmol) and sodium bicarbonate (NaHCO₃) (9.7 g, 115 mmol) were placed in a round bottom flask (RBF) and dissolved in a mixed solution of 72 mL of tetrahydrofuran (THF) and 7 mL of water (H₂O). Benzoyl chloride (BzCl) (7.36 mL, 63.4 mmol) was slowly added over 5 minutes at 0° C. and stirred at room temperature for 20 hours. The reaction solvent was distilled under reduced pressure to remove some of the THF, water was added, and organic substances was extracted with dichloromethane (DCM). The obtained organic layer was washed with brine, dried with Na₂SO₄, and filtered. The filtrate was concentrated under reduced pressure, and the residue was purified by using silica gel column chromatography to obtain compound A1-1 (6.98 g, 80%). The produced compound was confirmed by ¹H-NMR.

¹H-NMR (500 MHz, CDCl₃) δ8.86 (s, 1H), 7.52 (m, 2H), 7.47 (m, 1H), 7.41 (m, 2H), 3.38 (s, 3H)

### 2) Synthesis of Compound A1

Compound A1-1 (6.9 g, 45.6 mmol) was placed in RBF and dissolved by adding 37 mL of pyridine. 4-vinylbenzenesulfonyl chloride (9.7 g, 47.9 mmol) was added at 0° C. and stirred at room temperature for 20 hours. After extracting organic substances by adding 200 mL of water and 200 mL of ethyl acetate (EA), the organic layer was washed at least three times with a saturated aqueous solution of ammonium chloride (NH₄Cl). The obtained organic layer was washed with brine, dried over Na₂SO₄, and filtered, and the filtrate was concentrated, and the resulting residue was purified by separation using silica gel column chromatography to obtain Compound A1 (8.8 g, 61%). The produced compound was confirmed by ¹H-NMR.

¹H-NMR (500 MHz, CD₂Cl₂) δ7.71-7.69 (m, 2H), 7.47-7.42 (m, 3H), 7.35-7.30 (m, 4H), 6.75 (dd, 1H), 5.93 (d, 1H), 5.51 (d, 1H), 3.48 (s, 3H)

### (2) Synthesis of Polymer P1

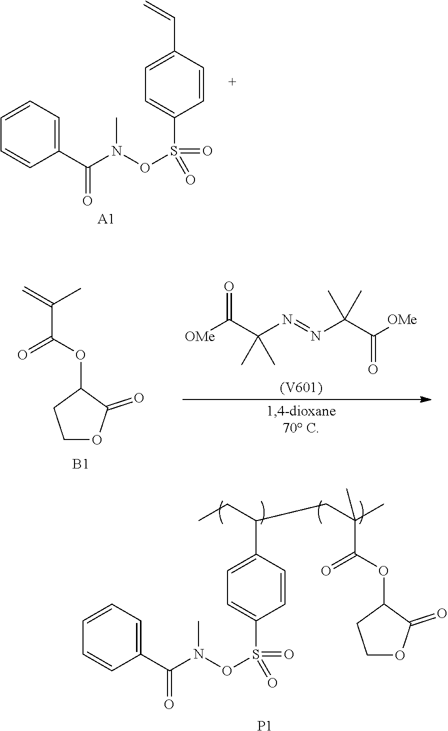

Monomer A1 (0.650 g, 2.05 mmol), 2-oxotetrahydrofuran-3-yl methacrylate (B1, 0.349 g, 2.05 mmol), and V601 (0.094 g, 0.410 mmol) were added to the vial, and were dissolved in 4.2 mL of 1,4-dioxane as a solvent. After stirring at 70° C. for 20 hours, the solid powder obtained by precipitation in a mixed solution of ethyl acetate: n-hexane=5:1 (volume ratio) was filtered to obtain polymer P1 (0.711 g).

### Synthesis Examples 2 to 10

Polymers P2 to P10 were synthesized using the same method as that used to synthesize Polymer P1 in Synthesis Example 1, except that the monomers in Table 1 below were used in molar ratios of Table 1 instead of Monomer A1 and Monomer B1.

Table 1

| | | Input cost | Weight average molecular | |
|---|---|---|---|---|
| Polymer | Monomer | (molar ratio) | weight (Mw) | PDI |
| P1 | A1 / B1 | 50 / 50 | 12500 | 1.55 |
| P2 | A1 / B2 | 50 / 50 | 6400 | 1.64 |
| P3 | A1 / B3 | 50 / 50 | 7600 | 2.18 |
| P4 | A1 / B1 / B3 | 40 / 50 / 10 | 9600 | 1.80 |
| P5 | A1 / B1 | 30 / 70 | 11400 | 1.93 |
| P6 | A1 / B1 | 20 / 80 | 6600 | 1.88 |
| P7 | A1 / B1 | 10/90 | 5400 | 1.91 |
| P8 | A1 / B1 / B3 | 20 / 60 / 20 | 11700 | 1.74 |
| P9 | A2 / B1 | 50 / 50 | 6600 | 1.77 |
| P10 | A1 / B4 | 50 / 50 | 13300 | 1.83 |

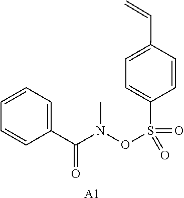

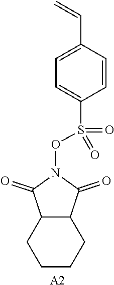

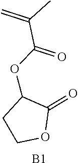

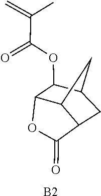

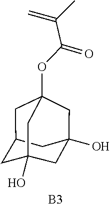

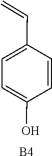

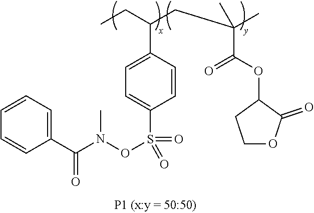

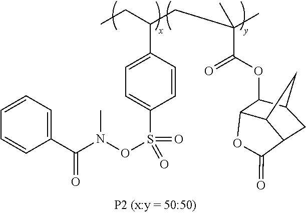

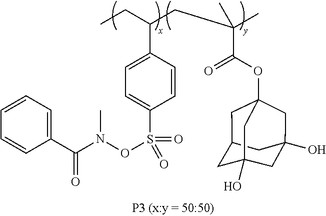

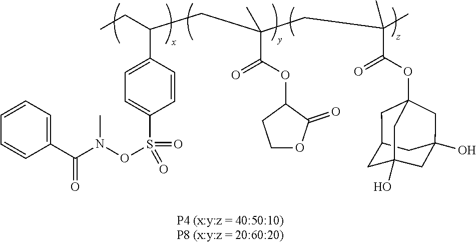

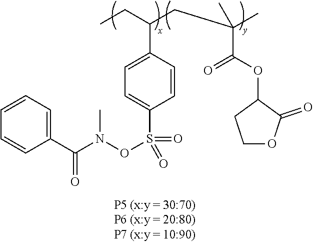

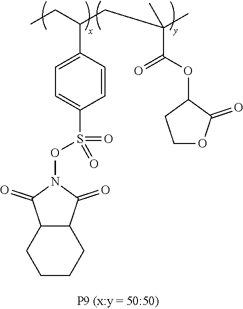

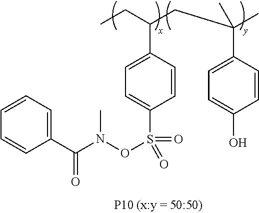

### Evaluation Example 1: Thin Film Phenomenon Evaluation

### (1) Terminology

E₀ refers to an exposure dose at a point where a thin film is completely developed (a thickness of the thin film is no longer decreased), and E₁ refers to an exposure dose at a point where development of the thin film is initiated. γ, indicating a contrast curve, is a value calculated by Equation 1 below.

$$γ = {[ log ( \frac{{E}_{0}}{{E}_{1}} ) ]}^{- 1} \qquad < Equation 1 >$$

### (2) Evaluation of Thin Film Phenomenon

The polymers synthesized in Synthesis Examples 1 to 10 were dissolved in the casting solvent of Table 2 below to 2.4 wt % to obtain a casting solution. An HMDS-treated silicon wafer was spin-coated with the casting solution at a speed of 1500 rpm and dried at 110° C. for 1 minute (PAB) to form a thin film having a thickness of 70 nm as shown in Table 2 below. Subsequently, the thin film was exposed to EUV having a wavelength of 13.5 nm at a dose of 0 to 100 mJ/cm², and a film obtained after the light exposure was immersed in a developer of Table 2 at 25° C. for 60 seconds, washed with water, and naturally dried, and then a thickness of the remaining film was measured using a film thickness measurement instrument (Filmetrics©, F-20) and shown in Table 3. FIG. 3A is a graph showing data of Polymer P1, FIG. 3B is a graph showing data of Polymer P2, FIG. 3C is a graph showing data of Polymer P3, FIG. 3D is a graph showing data of Polymer P4, FIG. 3E is a graph showing data of Polymer P5, FIG. 3F is a graph showing data of Polymer P6, FIG. 3G is a graph showing data of Polymer P8, FIG. 3H is a graph showing data of Polymer P9, FIG. 3I is a graph showing data of Polymer P10, and FIG. 3J is a graph showing data of Polymer P7.

TABLE 2

| Polymer | Casting solvent | Developer |
|---|---|---|
| P1 | Cyclopentanone | 2.38 wt % TMAH aqueous |
| | | solution |
| P2 | Cyclopentanone | 2.38 wt % TMAH aqueous |
| | | solution |
| P3 | Cyclopentanone | 2.38 wt % TMAH aqueous |
| | | solution |
| P4 | Cyclopentanone | 2.38 wt % TMAH aqueous |
| | | solution |
| P5 | Cyclopentanone | 2.38 wt % TMAH aqueous |
| | | solution |
| P6 | Cyclopentanone | 2.38 wt % TMAH aqueous |
| | | solution |
| P7 | Cyclopentanone | 2.38 wt % TMAH aqueous |
| | | solution |
| P8 | Cyclopentanone | 2.38 wt % TMAH aqueous |
| | | solution |
| P9 | Cyclopentanone | 2.38 wt % TMAH aqueous |
| | | solution |
| P10 | Cyclopentanone | 2.38 wt % TMAH aqueous |
| | | solution |

TABLE 3

| | | | | Contrast curve | | |
|---|---|---|---|---|---|---|
| | | | Composition | E₁ | E₀ | |
| Composition | Polymer | Monomer | ratio | (mJ/cm²) | (mJ/cm²) | γ |
| Example 1 | P1 | A1 / B1 | 50 / 50 | 33.6 | 40.1 | 5.67 |
| Example 2 | P2 | A1 / B2 | 50 / 50 | 72.5 | 105.1 | 2.63 |
| Example 3 | P3 | A1 / B3 | 50 / 50 | 40.3 | 68.5 | 1.92 |
| Example 4 | P4 | A1 / B1 / B3 | 40 / 50 / 10 | 18.3 | 31.3 | 1.89 |
| Example 5 | P5 | A1 / B1 | 30 / 70 | 20.1 | 37.0 | 1.6 |
| Example 6 | P6 | A1 / B1 | 20 / 80 | 3.5 | 13.1 | 0.7 |
| Example 7 | P8 | A1 / B1 / B3 | 20 / 60 / 20 | 3.3 | 10.0 | 0.8 |
| Example 8 | P9 | A2 / B1 | 50 / 50 | 25.3 | 53.9 | 1.47 |
| Comparative | P10 | A1 / B4 | 50 / 50 | not measured | | |
| Example 1 | | | | | | |
| Comparative | P7 | A1 / B1 | 10 / 90 | 3.0 | 37.0 | 0.36 |
| Example 2 | | | | | | |

Referring to Table 3, it was confirmed that solubility of all of the synthesized polymers of Examples 1 to 8 in the developer changed after exposure to EUV rays. Also, it was confirmed that most of the synthesized polymers of Examples 1 to 8 had improved sensitivity to change in solubility to the developer even at a low dose of 30 mJ/cm² or less, or had a relatively large γ.

However, in the case of Comparative Example 1, no change in contrast occurred after EUV exposure, so the E₀ value could not be specified, and accordingly, the E₁ and γ values could not be specified.

In addition, in the case of Comparative Example 2, it was confirmed that γ was relatively very small, and it was confirmed that Comparative Example 2 could not effectively control the difference in solubility of the polymer depending on exposure and non-exposure. In other words, it was confirmed that Comparative Example 2 was not suitable for patterning.

According to embodiments of the disclosure, provided are a polymer having physical properties changing even at a low dose, a resist composition including the same, and a method of forming a pattern using the same.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A polymer comprising:
at least 20 mol % of a first repeating unit represented by Formula 1, 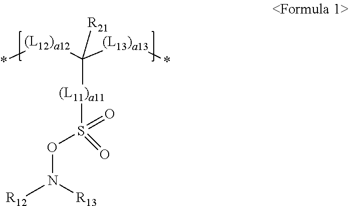
wherein the polymer does not include a repeating unit A including at least one selected from an aryl group substituted with a hydroxy group and a heteroaryl group substituted with a hydroxy group,
wherein in Formula 1,
L₁₁ to L₁₃ are each independently: a single bond; O; S; C(═O); C(═O)O; OC(═O);
C(═O)NH; NHC(═O); S(═O); S(═O)₂; S(═O)₂O; OS(═O)₂; or a linear, branched or cyclic C₁-C₃₀ divalent hydrocarbon group optionally including a heteroatom,
a11 to a13 are each independently an integer from 1 to 4,
R₁₁ to R₁₃ are each independently: hydrogen; deuterium; a halogen; a cyano group; a hydroxy group; an amino group; a carboxylate group; a thiol group; a carbonyl moiety; an amide moiety; an ester moiety; a sulfonate moiety; a carbonate moiety; a carbamate moiety; a lactone moiety; a sultone moiety; a carboxylic anhydride moiety; or
a linear, branched or cyclic C₁-C₃₀ monovalent hydrocarbon group optionally including a heteroatom,
R₁₂ and R₁₃ are optionally bound to each other to form a ring, and
* is a binding site with an adjacent atom.

2. The polymer of claim 1,
wherein L₁₁ to L₁₃ are each independently: a single bond; O; S; C(═O); C(═O)O; OC(═O); C(═O)NH; NHC(═O); S(═O); S(═O)₂; S(═O)₂O; OS(═O)₂; a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

3. The polymer of claim 1,
wherein R₁₁ is selected from: hydrogen; deuterium; a halogen; a cyano group; a hydroxy group; an amino group; a carboxylate group; a thiol group; an amide moiety; an ester moiety; and a C₁-C₂₀ alkyl group, a C₃-C₂₀ cycloalkyl group and a C₆-C₂₀ aryl group, which are unsubstituted or substituted with deuterium, a halogen, a cyano group, a hydroxy group, an amino group, a carboxylate group, a thiol group, an amide moiety, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

4. The polymer of claim 1,
wherein R₁₂ and R₁₃ are each independently selected from: hydrogen; deuterium; —C(═O)R₁₄; —C(R₁₄)═NR₁₅; —OR₁₄; —NR₁₄R₁₅; —S(═O)R₁₄; —S(═O)₂R₁₄; —S(═O)₂OR₁₄; and a C₁-C₂₀ alkyl group, a C₁-C₂₀ halogenated alkyl group, a C₃-C₂₀ cycloalkyl group, a C₆-C₂₀ aryl group and a C₁-C₂₀ heteroaryl group, which are unsubstituted or substituted with deuterium, a halogen, a hydroxyl group, a cyano group, a nitro group, a carboxylate group, an amino group, an ether moiety, a carbonyl moiety, an ester moiety, a sulfonate moiety, a carbonate moiety, a carbamate moiety, an amide moiety, a lactone moiety, a sultone moiety, a carboxylic acid anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, or any combination thereof, and
R₁₄ and R₁₅ are each independently selected from: hydrogen; deuterium; and a C₁-C₂₀ alkyl group, a C₁-C₂₀ halogenated alkyl group, a C₃-C₂₀ cycloalkyl group, a C₆-C₂₀ aryl group and a C₁-C₂₀ heteroaryl group, which are unsubstituted or substituted with deuterium, a halogen, a hydroxyl group, a cyano group, a nitro group, a carboxylate group, an amino group, an ether moiety, a carbonyl moiety, an ester moiety, a sulfonate moiety, a carbonate moiety, a carbamate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, or any combination thereof.

5. The polymer of claim 1,
wherein R₁₂ and R₁₃ are each independently selected from: hydrogen; deuterium; —C(═O)R₁₄; —C(R₁₄)═NR₁₅; —S(═O)R₁₄; —S(═O)₂R₁₄; —S(═O)₂OR₁₄; and a C₁-C₂₀ alkyl group, a C₁-C₂₀ halogenated alkyl group, a C₃-C₂₀ cycloalkyl group, a C₆-C₂₀ aryl group and a C₁-C₂₀ heteroaryl group, which are unsubstituted or substituted with deuterium, a halogen, a hydroxyl group, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof, and
R₁₄ and R₁₅ are each independently selected from: hydrogen; deuterium; and a C₁-C₂₀ alkyl group, a C₁-C₂₀ halogenated alkyl group, a C₃-C₂₀ cycloalkyl group, a C₆-C₂₀ aryl group and a C₁-C₂₀ heteroaryl group, which are unsubstituted or substituted with deuterium, a halogen, a hydroxyl group, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

6. The polymer of claim 1,
wherein R₁₂ and R₁₃ are each independently selected from: —C(═O)R₁₄; —C(R₁₄)═NR₁₅; —S(═O)₂R₁₄; and a C₁-C₂₀ alkyl group, a C₆-C₂₀ aryl group and a C₁-C₂₀ heteroaryl group, which are unsubstituted or substituted with deuterium, a halogen, a hydroxyl group, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof, and
R₁₄ and R₁₅ are each independently selected from: hydrogen; deuterium; and a C₁-C₂₀ alkyl group, a C₆-C₂₀ aryl group and a C₁-C₂₀ heteroaryl group, which are unsubstituted or substituted with deuterium, a halogen, a hydroxyl group, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof.

7. The polymer of claim 1,
wherein *—N(R₁₂)R₁₃ in Formula 1 is represented by any one of Formulae 4-1 to 4-7: 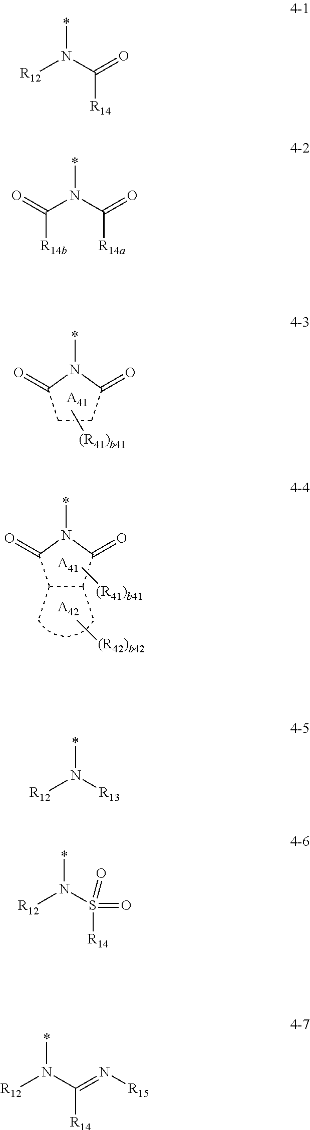
wherein in Formulae 4-1 to 4-7,
R₁₂ and R₁₃ are each independently selected from a C₁-C₂₀ alkyl group, a C₆-C₂₀ aryl group, and a C₁-C₂₀ heteroaryl group, which are unsubstituted or substituted with deuterium, a halogen, a hydroxyl group, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof,
R₁₄, R₁₅, R₁₄ₐ and R_{14b} are each independently selected from: hydrogen; deuterium; and a C₁-C₂₀ alkyl group, a C₆-C₂₀ aryl group and a C₁-C₂₀ heteroaryl group, which are unsubstituted or substituted with deuterium, a halogen, a hydroxyl group, a cyano group, a nitro group, a carbonyl moiety, a C₁-C₂₀ alkyl group, a C₁-C₂₀ halogenated alkyl group, a C₃-C₂₀ cycloalkyl group, a C₆-C₂₀ aryl group, a C₁-C₂₀ heteroaryl group, or any combination thereof,
two adjacent groups among R₁₂ to R₁₅, R₁₄ₐ, and R_{14b} are optionally bound to each other to form a ring,
A₄₁ and A₄₂ are each independently a C₁-C₃₀ cyclic alkyl group optionally including a heteroatom or a C₁-C₃₀ aryl group optionally including a heteroatom,
R₄₁ and R₄₂ are each independently hydrogen, deuterium, a halogen, a hydroxyl group, a cyano group, a nitro group, a C₁-C₂₀ alkyl group, a C₁-C₂₀ halogenated alkyl group, a C₃-C₂₀ cycloalkyl group, a C₆-C₂₀ aryl group, or a C₁-C₂₀ heteroaryl group,
b41 and b42 are each independently an integer from 1 to 10, and
* is a binding site with an adjacent atom.

8. The polymer of claim 1,
wherein *—N(R₁₂)R₁₃ in Formula 1 is represented by any one of Formulae 4-11 to 4-40: 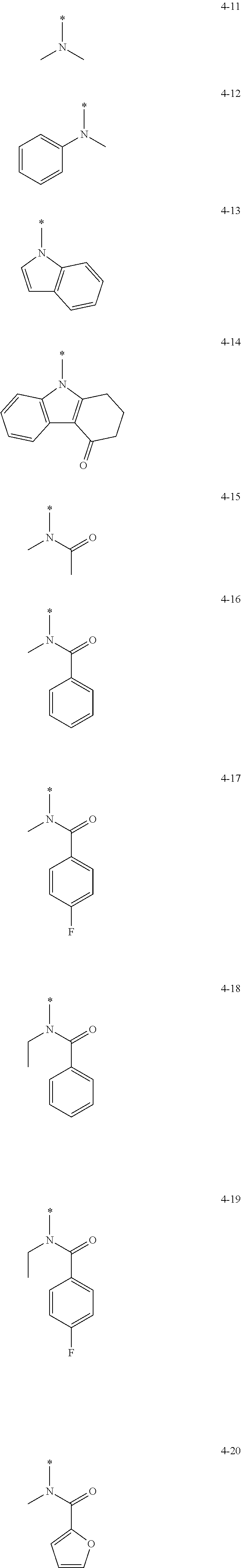 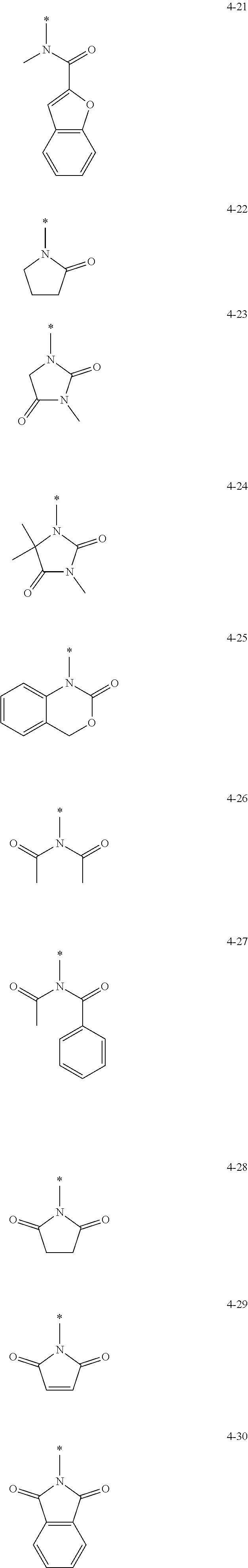 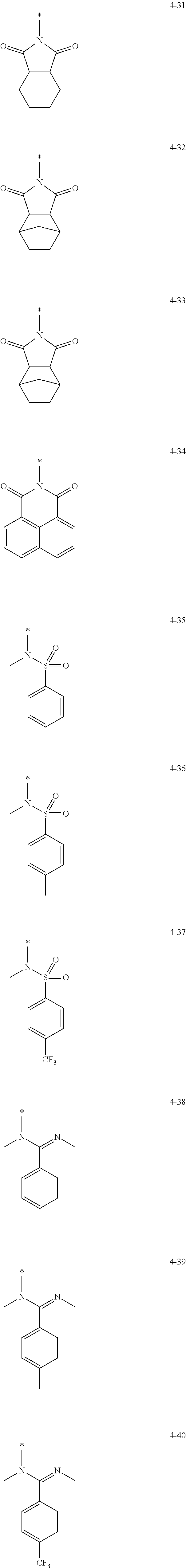
wherein in Formulae 4-11 to 4-40,
* is a binding site with an adjacent atom.

9. The polymer of claim 1,
wherein the first repeating unit is selected from Group I below:

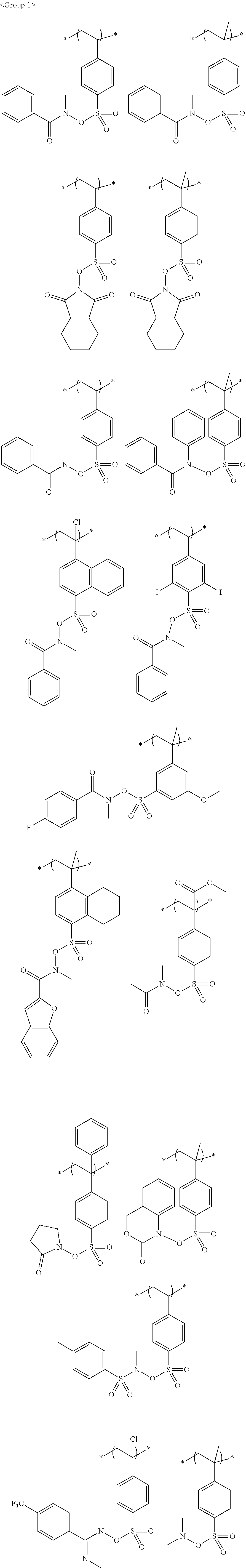

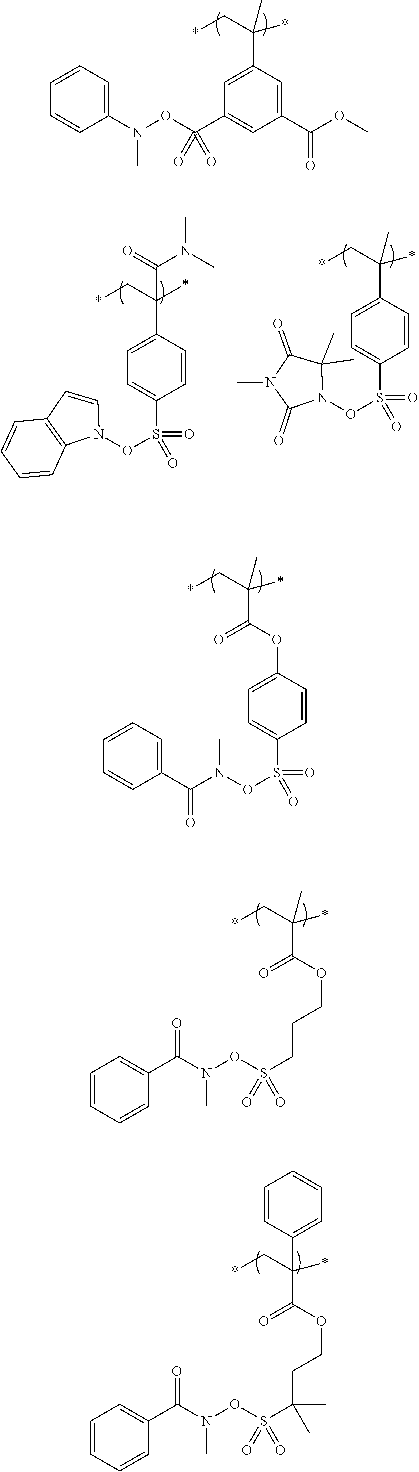

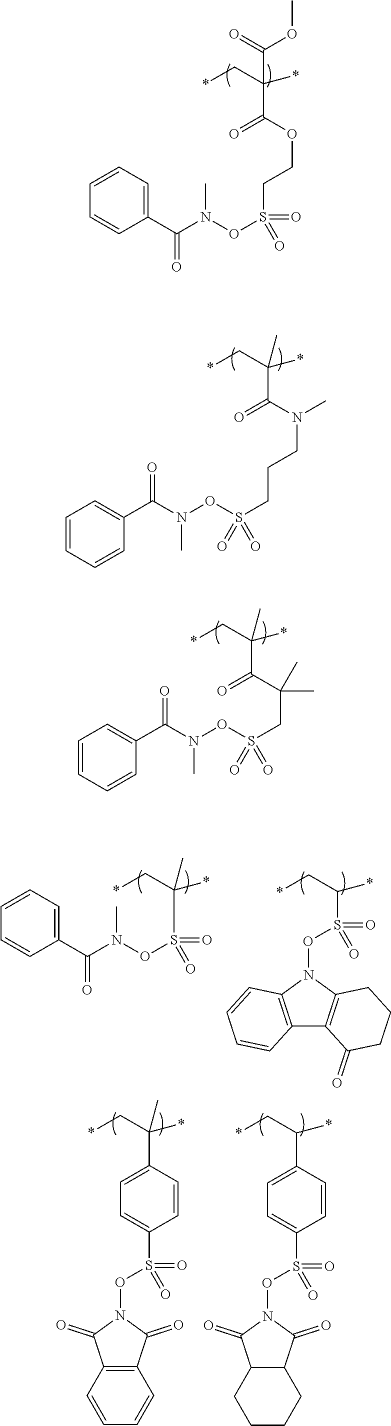

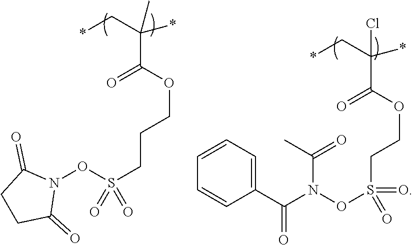

10. The polymer of claim 1, wherein
the polymer comprises at least 30 mol % of the first repeating unit represented by Formula 1.

11. The polymer of claim 1, wherein
the polymer comprises at least 50 mol % of the first repeating unit represented by Formula 1.

12. The polymer of claim 1, further comprising:
a second repeating unit represented by Formula 2: 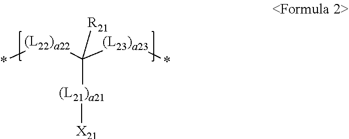
wherein in Formula 2,
L₂₁ to L₂₃ are each independently: a single bond; O; S; C(═O); C(═O)O; OC(═O); C(═O)NH; NHC(═O); S(═O)₂O; OS(═O)₂; or a linear, branched or cyclic C₁-C₃₀ divalent hydrocarbon group optionally including a heteroatom,
a21 to a23 are each independently an integer from 1 to 4,
R₂₁ is: hydrogen; deuterium; a halogen; a cyano group; a hydroxy group; an amino group; a carboxylate group; a thiol group; a carbonyl moiety; an ester moiety; a sulfonate moiety; a carbonate moiety; a carbamate moiety; a lactone moiety; a sultone moiety; a carboxylic anhydride moiety; or a linear, branched or cyclic C₁-C₃₀ monovalent hydrocarbon group optionally including a heteroatom,
X₂₁ is a non-acid labile group, and
* is a binding site with an adjacent atom.

13. The polymer of claim 12,
wherein X₂₁ is: hydrogen; a halogen; a cyano group; a hydroxy group; a carboxylate group; a thiol group; an amino group; or a linear, branched or cyclic C₁-C₃₀ monovalent hydrocarbon group optionally including one or more polar moieties selected from a halogen, a cyano group, a hydroxy group, a carboxylate group, a thiol group, O, C═O, C(═O)O, OC(═O), S(═O)O, OS(═O), a lactone moiety, a sultone moiety and a carboxylic anhydride moiety.

14. The polymer of claim 12,
wherein X₂₁ is selected from hydrogen, a hydroxy group, a C₁-C₁ alkyl group, and groups represented by Formulae 5-1 to 5-15: 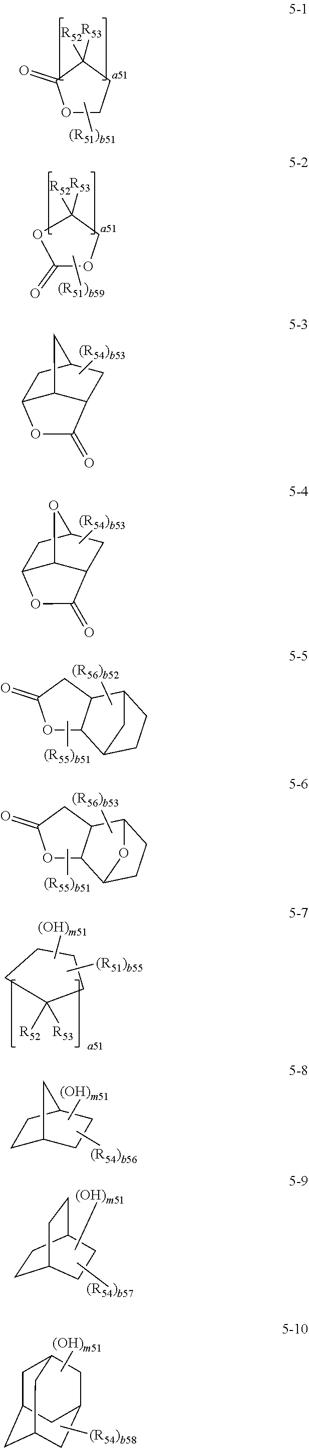 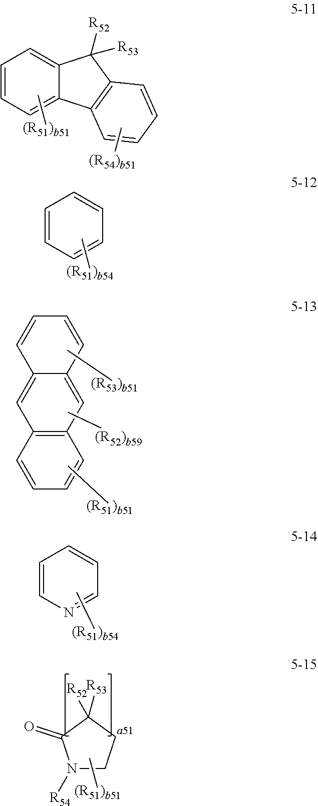
wherein in Formulae 5-1 to 5-15,
a51 is 1 or 2,
R₅₁ to R₅₆ are each independently: a binding site with an adjacent atom; hydrogen; deuterium; a halogen; a cyano group; a hydroxy group; an amino group; a carboxylate group; a thiol group; a carbonyl moiety; an ester moiety; a sulfonate moiety; a carbonate moiety; a carbamate moiety; a lactone moiety; a sultone moiety; a carboxylic anhydride moiety; or a linear, branched or cyclic C₁-C₃₀ monovalent hydrocarbon group optionally including a heteroatom,
one of R₅₁ to R₅₃, one of R₅₄, and one of R₅₅ and R₅₆ is a binding site with an adjacent atom,
b51 is selected from integers of 1 to 4,
b52 is selected from integers of 1 to 10,
b53 is selected from integers from 1 to 8,
b54 is selected from integers from 1 to 5,
b55 is selected from integers from 1 to 7,
b56 is selected from integers from 1 to 11,
b57 is selected from integers from 1 to 13,
b58 is selected from integers from 1 to 15,
b59 is selected from 1 and 2, and
m51 is selected from integers from 1 to 4.

15. The polymer of claim 12,
wherein the second repeating unit is a polymer structure selected from Group II:

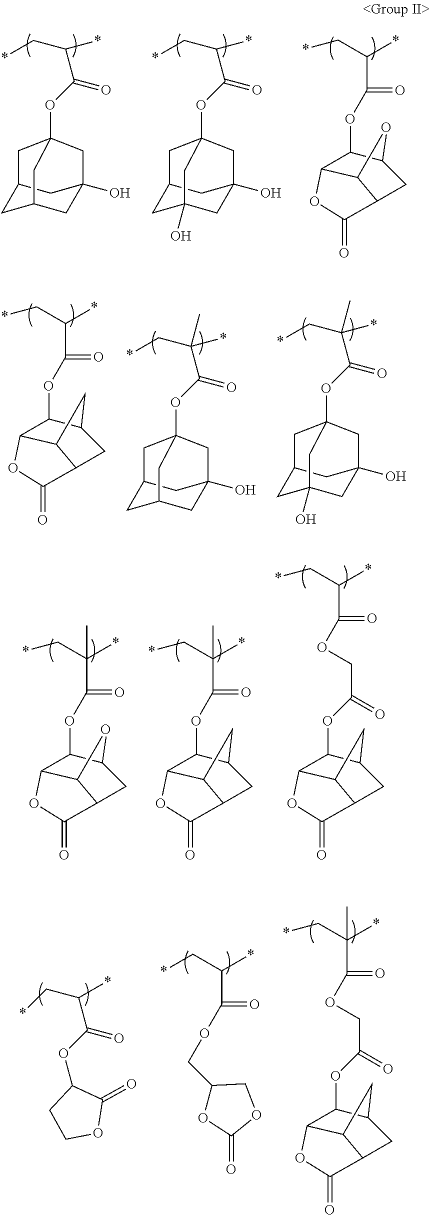

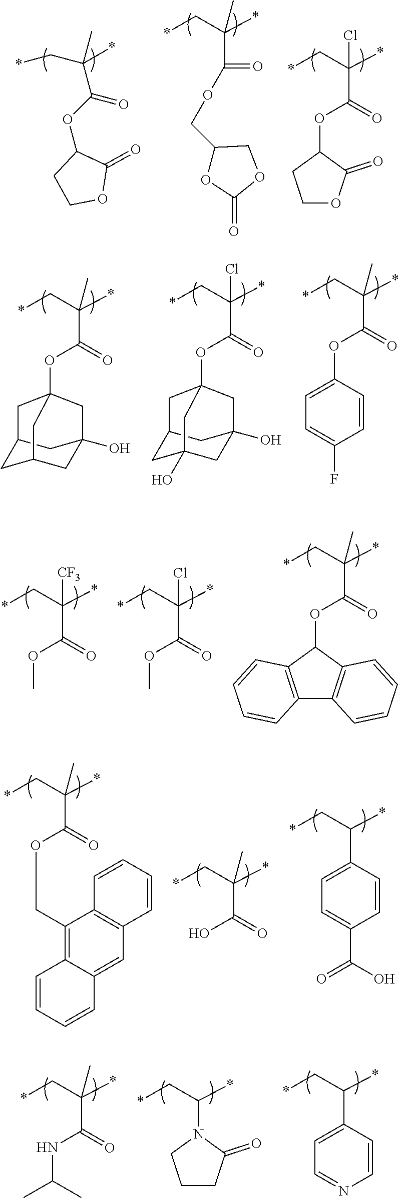

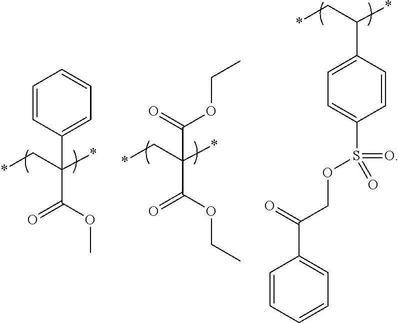

16. A resist composition comprising:
the polymer of claim 1; and
an organic solvent.

17. The resist composition of claim 16,
wherein, other than the polymer, the resist composition substantially does not comprise a compound having a molecular weight of 1,000 or more.

18. A method of forming a pattern, the method comprising:
forming a resist film by applying the resist composition of claim 16 onto a substrate;
exposing at least a portion of the resist film to high-energy rays to provide an exposed resist film; and
developing the exposed resist film using a developer.

19. The method of claim 18, wherein
the exposing at least a portion of the resist film is performed by at least one of irradiating ultraviolet rays, deep ultraviolet (DUV) rays, extreme ultraviolet (EUV) rays, X-rays, γ-rays, electron beams (EBs), or α-rays.

20. The method of claim 18,
wherein the exposed resist film includes an exposed region and an unexposed region, and
the exposed region is removed during the developing.
